(19) United States
(12) Patent Application Publication
(10) Pub. No.: US 2025/0116933 A1
(43) Pub. Date: Apr. 10, 2025

(54) MULTIBLOCK COPOLYMERS, PHOTORESIST COMPOSITIONS INCLUDING THE SAME, AND PATTERN FORMATION METHODS

(71) Applicant: DuPont Electronic Materials International, LLC, Marlborough, MA (US)

(72) Inventors: Wenxu Zhang, Natick, MA (US); Jingyi Li, Newton, MA (US); Huan He, Hopkinton, MA (US); Mingqi Li, Shrewsbury, MA (US); Xisen Hou, Marlborough, MA (US)

(21) Appl. No.: 18/481,018

(22) Filed: Oct. 4, 2023

(51) Int. Cl. G03F 7/039; C08F 293/00; G03F 7/00; G03F 7/004

(52) U.S. Cl. CPC G03F 7/0397; C08F 293/00; G03F 7/0035; G03F 7/0048

(57) ABSTRACT

A block copolymer including a first block comprising two or more structurally different repeating units; a second block comprising two or more structurally different repeating units; a repeating unit of the first block comprises an acid-labile group, a lactone group, a salt group, or a hydroxyaryl group; and a repeating unit of the second block comprises an acid-labile group, a lactone group, a salt group, or a hydroxyaryl group, wherein the two or more structurally different repeating units of the first block are the same as the two or more structurally different repeating units of the second block.

### FIELD

The present invention relates to multiblock copolymers for photoresist compositions and to pattern formation methods using such photoresist compositions. The invention finds applicability in lithographic applications in the semiconductor manufacturing industry.

### BACKGROUND

Photoresist materials are photosensitive compositions typically used for transferring an image to one or more underlying layers such as a metal, semiconductor, or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

State-of-the-art lithographic patterning processes currently employ ArF (193 nm) immersion scanners to process wafers at dimensions that are less than 60 nanometers (nm). Pushing ArF lithography to sub-60 nm critical dimensions creates several challenges for the photoresist capabilities in terms of process window, line width roughness (LWR), and other critical parameters for high volume manufacturing of integrated circuits. All of these parameters must be addressed in next-generation formulations. As pattern dimensions are reduced in advanced nodes, LWR values have not been concurrently reduced at the same rate, creating a significant source of variation during processing at those leading-edge nodes. Process window improvements are also useful for achieving high yield in integrated circuit manufacturing.

Extreme ultraviolet lithography (EUV lithography) is another leading technology for high volume semiconductor wafer manufacturing at sub-20 nm critical dimensions.

Photoresist polymers are often used in photoresist compositions to achieve useful properties during photolithographic processing. However, the non-uniform distribution of polymer functionality between polymer chains and/or variations along the polymer backbone when using polymers prepared by conventional methods can present challenges when trying to pattern at higher resolutions.

There remains a continued need for photoresist compositions to address one or more problems associated with photolithographic patterning at sub-60 nm critical dimensions. In particular, there is a continuing need for photoresist compositions that can achieve improved resolution and reduced LWR.

### SUMMARY

An aspect provides a block copolymer including a first block comprising two or more structurally different repeating units; a second block comprising two or more structurally different repeating units; a repeating unit of the first block comprises an acid-labile group, a lactone group, a salt group, or a hydroxyaryl group; and a repeating unit of the second block comprises an acid-labile group, a lactone group, a salt group, or a hydroxyaryl group, wherein the two or more structurally different repeating units of the first block are the same as the two or more structurally different repeating units of the second block.

Another aspect provides a polymer including one or more block copolymers as described herein bonded to another part of the polymer.

Still another aspect provides a photoresist composition including a block copolymer as provided herein and a solvent.

Another aspect provides a pattern forming method including forming on a substrate a photoresist composition layer from the photoresist composition, pattern-wise exposing the photoresist composition layer to activating radiation, and developing the exposed photoresist composition layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O-”; “carboxyl” and “carboxylic acid group” refer to a group having the formula “—C(O)-OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O-”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel's Rule (4n+2 π electrons) and includes carbon atoms in the ring; the term “heteroaromatic group” refers to an aromatic group that includes one or more heteroatoms (e.g., 1-4 heteroatoms) selected from N, O, and S instead of a carbon atom in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O-”; and “arylthio” refers to “aryl-S-”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl” refers to an alkyl group having at least one heteroatom instead of carbon; “heterocycloalkyl” refers to a cycloalkyl group having 1-4 heteroatoms as ring members instead of carbon; “heterocycloalkylene” refers to a heterocycloalkyl group having a valence of two; “heteroaryl” refers to an aromatic 4-8 membered monocyclic, 8-12 membered bicyclic, or 11-14 membered tricyclic ring system having 1-4 heteroatoms (if monocyclic), 1-6 heteroatoms (if bicyclic), or 1-9 heteroatoms (if tricyclic) that are each independently selected from N, O, S, Si, or P (e.g., carbon atoms and 1-3, 1-6, or 1-9 heteroatoms of N, O, or S, if monocyclic, bicyclic, or tricyclic, respectively). Examples of heteroaryl groups include pyridyl, furyl (furyl or furanyl), imidazolyl, benzimidazolyl, pyrimidinyl, thiophenyl or thienyl, quinolinyl, indolyl, thiazolyl, and the like; and “heteroarylene” refers to a heteroaryl group having a valence of two.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens. It is to be understood that substitution of a group with a halogen atom is not to be considered a heteroatom-containing group, because a halogen atom does not replace a carbon atom.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom's normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl(C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O) H), carboxylic acid or an alkali metal or ammonium salt thereof; esters (including acrylates, methacrylates, and lactones) such as C₂₋₆ alkyl esters (—C(O)O-alkyl or —OC(O)-alkyl) and C₇₋₁₃ aryl esters (—C(O)O-aryl or —OC(O)-aryl); amido (—C(O) NR₂ wherein R is hydrogen or C₁₋₆ alkyl), carboxamido (—CH₂C(O) NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl(CH₃C₆H₄SO₂—).

As used herein, when a definition is not otherwise provided, a “divalent linking group” and a “linking group” refer to a group including one or more of —O—, —S—, —Te—, —Se—, —C(O)—, —C(O)O—, —N(R′)—, —C(O) N(R′)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R′)—, —C(O) N(R′)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R′)—, —C(O) N(R′)—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

As used herein, an “acid-labile group” refers to a group in which a bond is cleaved by the action of an acid, optionally and typically with thermal treatment, resulting in formation of a polar group, such as a carboxylic acid or alcohol group. In some instances, the acid-labile group may be formed on a polymer, and optionally and typically with a moiety connected to the cleaved bond becoming disconnected from the polymer. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

The present invention relates to multiblock copolymers, which provides a solution to compositional variations in polymers that are used for photoresist compositions. For example, when a polymer is prepared by free radical polymerization or made using controlled-radical dump and run methods, it often results in homogeneity issues between polymer chains in the composition or inhomogeneity along the polymer backbone. In a typical free radical copolymerization or controlled radical copolymerization (or other chain copolymerization techniques), the comonomers distribute unevenly along the polymer backbone, or between different polymer chains, due to the difference in their incorporation rates. The present invention provides a multiblock copolymer, where the polymer chains are broken down into a few blocks, where two or more blocks may have the same particular composition of repeating units, and optionally the same composition gradient, such that the multiblock copolymer can provide a substantially uniform distribution of repeating units along the polymer backbone overall.

The use of multiple block structures allows the final polymer properties to be tuned based on monomer selection and gradient. For example, the properties obtained in traditional copolymers are typically an average of the properties imparted by the resultant monomers incorporated, while block copolymers lead to a composite material containing the characteristic properties inherent to each parent polymer block segment. The gradient structure using multiple block structures allows for the tuning of each block segment and further simplifies the copolymer synthesis process. U.S. Pat. No. 6,887,962 and patent application 2004/0180019 give examples of gradient copolymers made by controlled radical polymerization (CRP).

When a copolymer segment is synthesized using a controlled radical polymerization (CRP) technique, it is termed a gradient copolymer. This type of copolymer is different from a copolymer obtained by a traditional free radical process and the copolymer properties will be dependent on the monomer composition, control agent employed, and polymerization conditions. For example, when polymerizing a monomer mix by traditional free radical polymerization, a statistical copolymer is produced. The polymers made at each instant during the polymerization are not the same in composition. Furthermore, due to the constant production of free radicals throughout the reaction and the constantly changing monomer ratio, the composition between different polymer chains will be non-uniform. During CRP, the chains remain active throughout the polymerization, thus the composition between different polymer chains are uniform but each chain will be a gradient in terms of composition. Thus, in a two monomer system where one monomer reacts faster than the other monomer, the distribution or ‘profile’ of the monomer units will be such that one monomer unit is higher in concentration at one end of the block.

Provided is a block copolymer including a first block including two or more structurally different repeating units; and a second block including two or more structurally different repeating units. A repeating unit of the first block includes an acid-labile group, a lactone group, a salt group, or a hydroxyaryl group; and a repeating unit of the second block includes an acid-labile group, a lactone group, a salt group, or a hydroxyaryl group, wherein the two or more structurally different repeating units of the first block are the same as the two or more structurally different repeating units of the second block. For example, the first block and the second block may each include two structurally different repeating units, three structurally different repeating units, or four or more structurally different repeating units, provided that the first block and the second block have the same structurally different repeating units.

It should be noted that the block copolymer may optionally further include other blocks (i.e., third, fourth, fifth, etc. blocks) that may be the same or different from the first block and the second block as described herein. In some embodiments, the block copolymer may further include a block that does not have the same structurally different repeating units as the first block and the second block. For example, the block copolymer may include a third block, where the third block includes repeating units that may be different from those of the first block and the second block. In other embodiments, the block copolymer may include a third block and a fourth block, where the third block includes repeating units that may be different from those of the first block and the second block, and the fourth block may include repeating units that are different from those of the first block, the second block, and the third block. The additional blocks of the block copolymer may each include a single repeating unit, or the additional block of the block copolymer may each include two or more structurally different repeating units. In some embodiments, when the block copolymer includes additional blocks, the additional blocks may each include two or more structurally different repeating units, wherein the two or more structurally different repeating units may be different or the same between each additional block and relative to the first block and the second block.

In some embodiments, every block of the block copolymer may have the same two or more structurally different repeating units. In other words, in some embodiments, the block copolymer does not include an additional block or plurality of blocks having polymerized units that are different from the repeating units in the first block and the second block.

The two or more structurally different repeating units of the first block and the two or more structurally different repeating units of the second block may be present in the first block and the second block in any suitable ratios, and, for example, the molar ratio of the two or more structurally different repeating units of the first block may be the same as or different from the molar ratio of the two or more structurally different repeating units of the second block. For example, a block copolymer may have a first block of repeating units A and B and a second block of repeating units A and B, where the ratios of repeating units A to repeating units B in the first block may be the same as or different from the ratios of repeating units A to repeating units B in the second block. When the block copolymer further includes additional block(s) besides the first block and the second block, each additional block may independently have structurally different repeating units in any suitable ratios.

In some embodiments, the two or more structurally different repeating units of the first block and the two or more structurally different repeating units of the second block may be present in the first block and the second block in substantially the same ratios, and each block has the same structural unit gradient direction from a first end to a second end of the block. For example, the two or more structurally different repeating units of the first block and the two or more structurally different repeating units of the second block may be present in the first block and the second block in substantially the same molar ratios based on total moles of repeating units in the respective first block and second block. As used herein, the term “structural unit gradient direction” may refer to a gradient based on molar ratio of repeating units. In some embodiments, every block of the block copolymer may have the same two or more structurally different repeating units, wherein the two or more structurally different repeating units of each block may be present in substantially the same ratios, and each block has the same structural unit gradient direction from a first end to a second end of the block.

As noted above, a repeating unit of the first block and the second block of the block copolymer includes an acid-labile group, a lactone group, a salt group, or a hydroxyaryl group. For example, in some embodiments, the first block and the second block may each include a repeating unit that includes an acid-labile group. In some embodiments, the first block and the second block may each include a repeating unit that includes a lactone group or a salt group. For example, in some embodiments, the first block and the second block of the block copolymer may each include a first repeating unit that includes an acid-labile group and a second repeating unit that includes a lactone group or a salt group.

In some embodiments, the first block and the second block of the block copolymer may each include a first repeating unit that includes an acid-labile group and a second repeating unit that includes a lactone group. In still other embodiments, the first block and the second block of the block copolymer may each include a first repeating unit that includes an acid-labile group, a second repeating unit that includes a first lactone group, and a third repeating unit that includes a second lactone group, wherein the first lactone group and the second lactone group are different. In still other embodiments, the first block and the second block of the block copolymer may each include a first repeating unit that includes a first acid-labile group, a second repeating unit that includes a second acid-labile group, and a third repeating unit that includes a lactone group, wherein the first acid-labile group and the second acid-labile group are different.

Suitable acid labile groups include, for example, tertiary alkyl ester groups, secondary or tertiary aryl ester groups, secondary or tertiary ester groups having a combination of alkyl and aryl groups, tertiary alkoxy groups, acetal groups, ketal groups, tertiary carbonate groups, and tertiary carbamate groups. Typically, the acid labile group may be an acetal group, a ketal group, a tertiary carbonate group, a tertiary carbamate group, or a tertiary ester group. As used herein, the “tertiary carbamate group” includes tertiary carbamate ester groups having alkyl groups, tertiary carbamate ester groups having aryl groups, and tertiary carbamate ester groups having a combination of alkyl and aryl groups. As used herein, the “tertiary carbonate group” includes tertiary carbonate ester groups having alkyl groups, tertiary carbonate ester groups having aryl groups, and tertiary carbonate ester groups having a combination of alkyl and aryl groups. Preferably, the acid liable group includes a tertiary ester group.

A repeating unit of the block copolymer may include an acid labile group that is represented by one or more of Formulae (1) to (5):

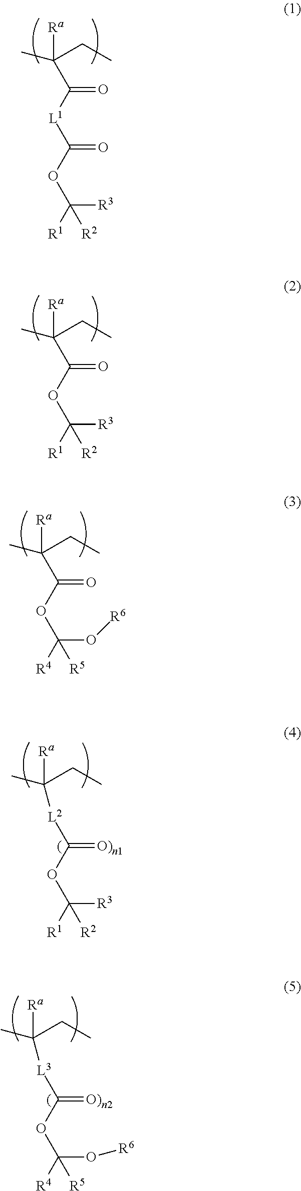

In Formulae (1) to (3), each R^{a} is independently hydrogen, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

In Formula (1), L1 is a divalent linking group. For example, L1 may be a divalent linking group including at least one carbon atom, at least one heteroatom, or a combination thereof. For example, L1 may include 1 to 10 carbon atoms and at least one heteroatom. In one or more embodiments, L1 may be —OCH₂—, —OCH₂CH₂O— or —N(R^{c})—, wherein R^{c} is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

In Formulae (1), (2), and (4), R¹ to R³ may each independently be hydrogen, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl; provided that only one of R¹ to R³ may be hydrogen, and provided that when one of R¹ to R³ is hydrogen, one or both of the others of R¹ to R³ are substituted or unsubstituted C₆₋₂₀ aryl or substituted or unsubstituted C₄₋₂₀ heteroaryl. Preferably, R¹ to R³ are each independently substituted or unsubstituted C₁₋₆ alkyl or substituted or unsubstituted C₃₋₁₀ cycloalkyl.

In Formulae (1), (2), and (4), any two of R¹ to R³ together optionally form a ring, and each of R¹ to R³ optionally may include as part of their structure one or more groups chosen from —O—, —C(O)—, —N(R^{c})—, —S—, —S(O)—, or —S(O)₂—, wherein R^{c} may be hydrogen, a straight chain or branched C₁₋₂₀ alkyl, monocyclic or polycyclic C₃₋₂₀ cycloalkyl, or monocyclic or polycyclic C₁₋₂₀ heterocycloalkyl. For example, any one or more of R¹ to R³ may be independently a group of the formula-CH₂C(═O) CH₍₃₋ₙ₎Yn, where each Y is independently substituted or unsubstituted C₁₋₃₀ heterocycloalkyl, and n is 1 or 2. For example, each Y may be independently substituted or unsubstituted C₁₋₃₀ heterocycloalkyl including a group of the formula-O(C^{a1})(C^{a2})O—, wherein C^{a1} and C^{a2} are each independently hydrogen or substituted or unsubstituted C₁₋₁₀ alkyl, and where C^{a1} and C^{a2} together optionally form a ring.

In Formulae (3) and (5), R⁴ and R⁵ may be each independently hydrogen, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl; and R⁶ may be substituted or unsubstituted C₁₋₂₀ alkyl, substituted or unsubstituted C₃₋₂₀ cycloalkyl, or substituted or unsubstituted C₁₋₃₀ heterocycloalkyl. Optionally, one of R⁴ or R⁵ together with R⁶ may form a heterocyclic ring. Preferably, R⁴ and R⁵ may be each independently hydrogen, substituted or unsubstituted C₁₋₂₀ alkyl, substituted or unsubstituted C₃₋₂₀ cycloalkyl, or substituted or unsubstituted C₁₋₂₀ heterocycloalkyl.

In Formulae (4) and (5), L2 and L3 are each independently a single bond or a divalent linking group. Preferably, L2 and L3 are each independently substituted or unsubstituted C₆₋₃₀ arylene or substituted or unsubstituted C₃₋₃₀ cycloalkylene. For example, in some embodiments, L3 does not include a (meth)acrylate group as part of its structure.

In Formulae (4) and (5), each of n1 and n2 may independently be 0 or 1. It is to be understood that when n1 or n2 is 0, the corresponding L2 or L3 group is connected directly to the respective oxygen atom.

Non-limiting examples of repeating units having an acid labile group include the following:

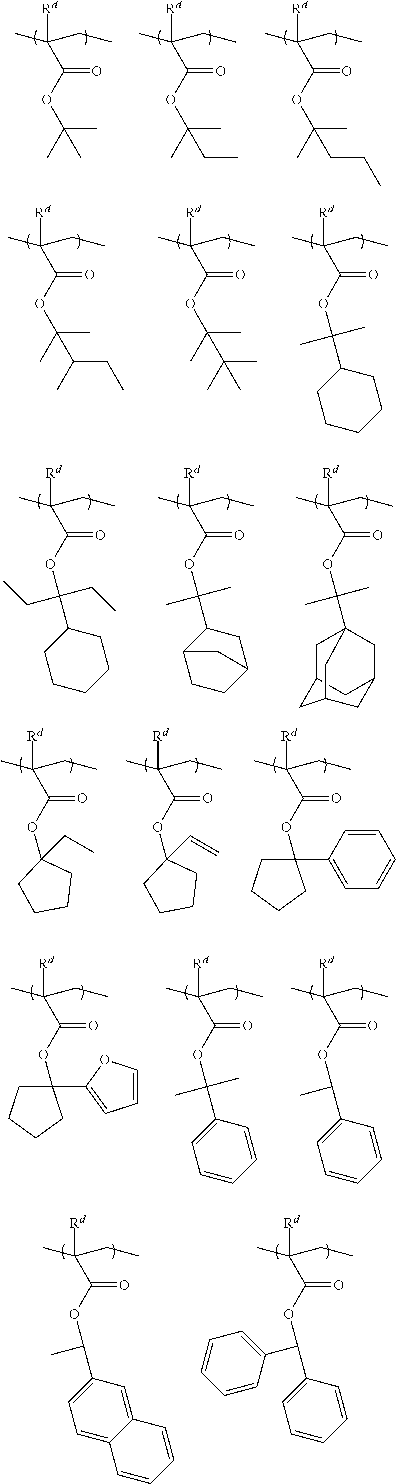

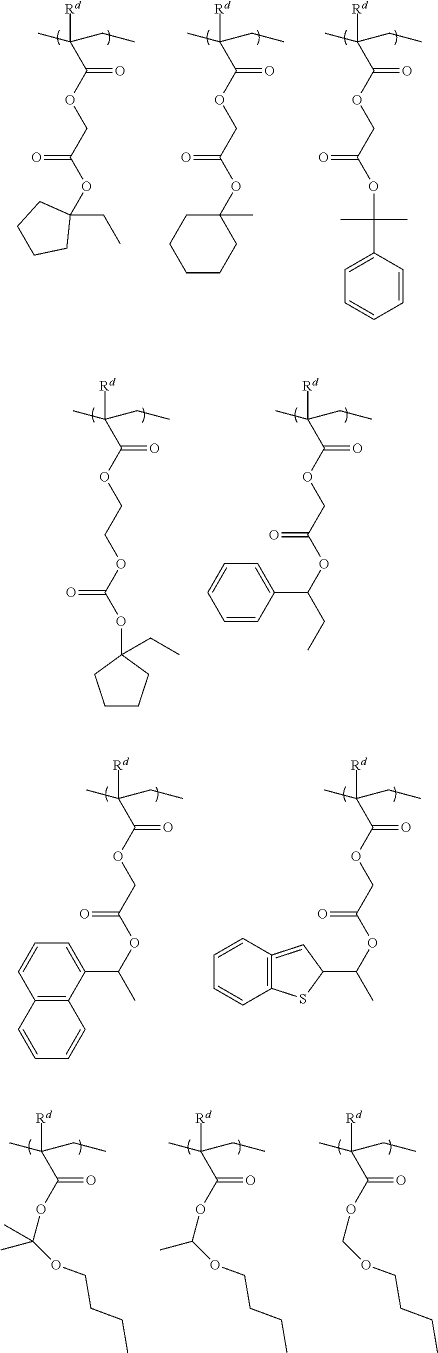

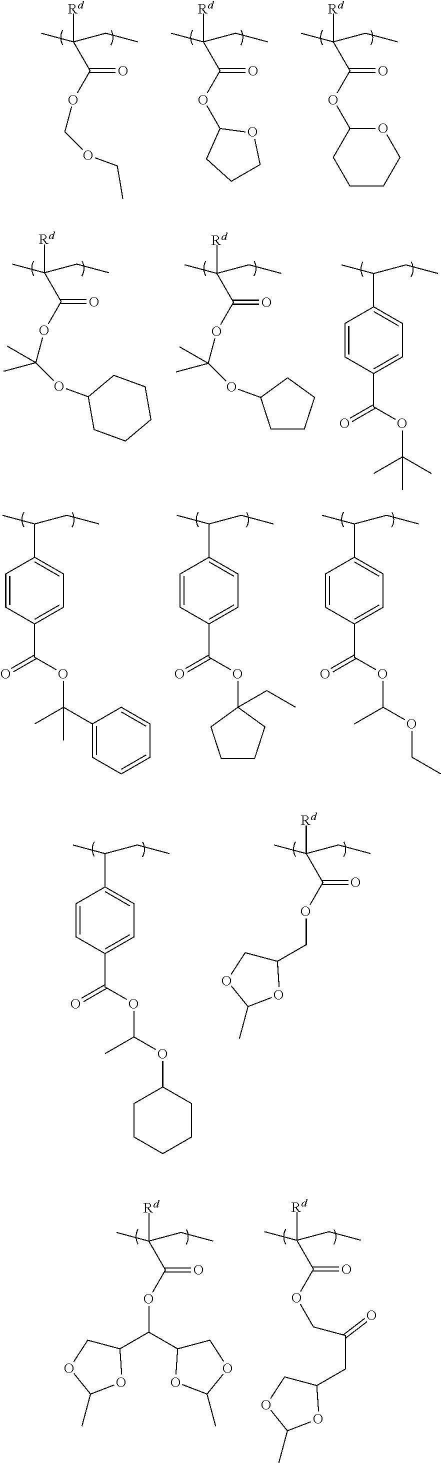

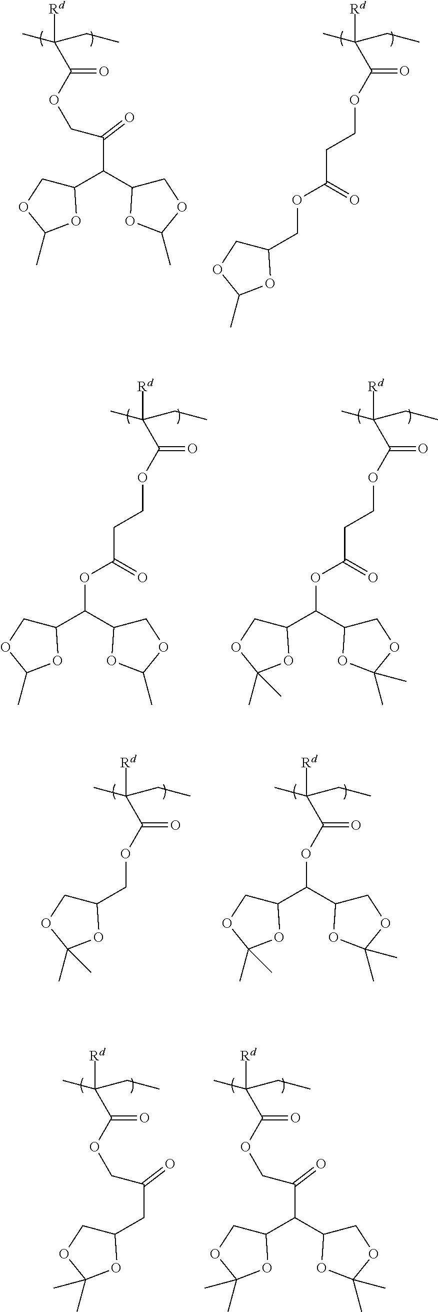

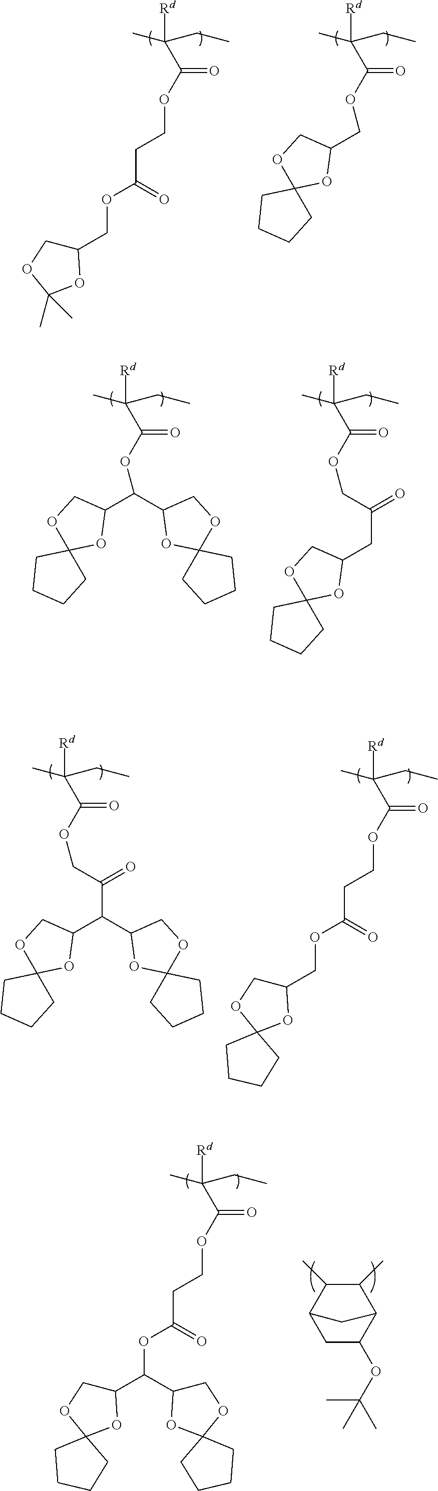

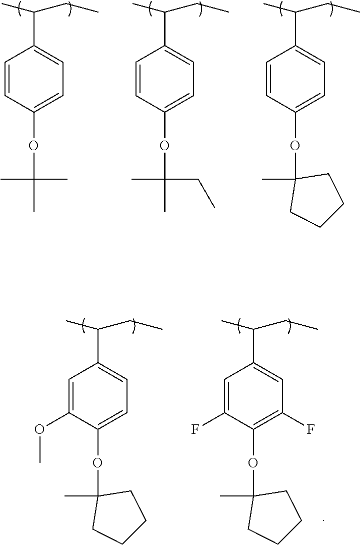

wherein R^{d} is hydrogen, halogen, substituted or unsubstituted C₁₋₆ alkyl, or substituted or unsubstituted C₃₋₆ cycloalkyl.

The repeating unit in a block of the block copolymer including an acid labile group typically may be present in an amount from 10 to 90 mole percent (mol %), more typically from 10 to 65 mol %, and still more typically from 15 to 60 mol %, based on total repeating units of the block. The repeating units including an acid labile group typically may be present in the block copolymer in an amount from 10 to 90 mol %, more typically from 10 to 65 mol %, and still more typically from 25 to 60 mol %, based on total repeating units of the block copolymer.

A repeating unit of the block copolymer may include a lactone group. For example, a repeating unit of the block copolymer may include a lactone group that is represented by Formula (6):

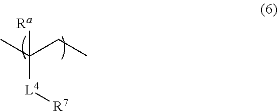

In Formula (6), R^{a} may be hydrogen, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (6), L4 may be a single bond or one or more divalent linking groups. For example, L4 may be —O—, —C(O)—, —C(O)O—, —N(R^{c})—, —C(O) N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L4 may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (6), R⁷ may be a monocyclic, polycyclic, or fused polycyclic C₄₋₂₀ lactone-containing group.

Non-limiting examples of lactone-containing repeating units of Formula (6) may include:

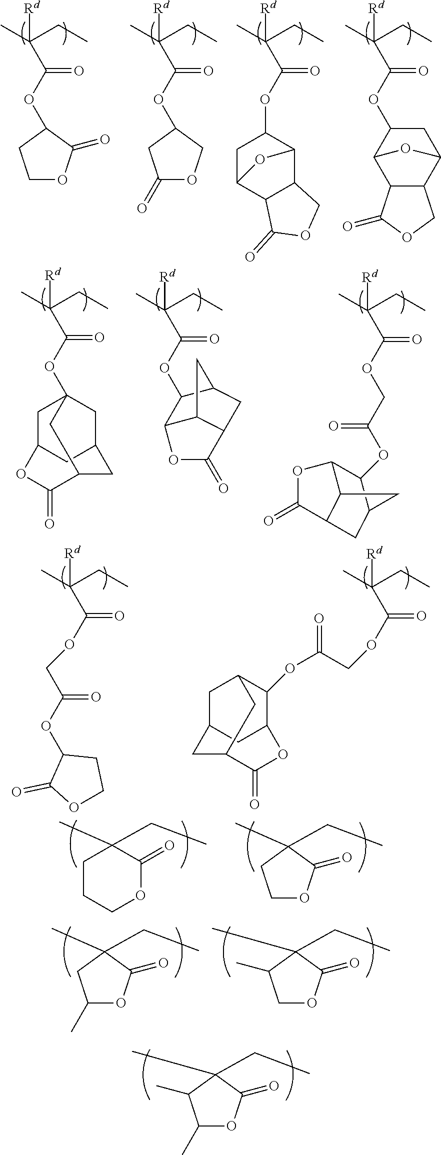

wherein R^{d} may be hydrogen, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

A repeating unit in a block of the block copolymer including a lactone group typically may be present in an amount from 20 to 90 mol %, more typically from 25 to 75 mol %, and still more typically from 30 to 70 mol %, based on total repeating units of the block. The repeating units including a lactone group typically may be present in the block copolymer in an amount from 20 to 90 mol %, more typically from 25 to 75 mol %, and still more typically from 30 to 70 mol %, based on total repeating units of the block copolymer.

A repeating unit of the block copolymer may include a salt group. As used herein, a “salt group” refers to a moiety having a positive charge and a negative charge, such as having a positively-charged or negatively-charged moiety that is bonded pendant to the backbone of the block copolymer. The repeating unit of the block copolymer including a salt group may comprise a photoacid generator (PAG) group or a photo-decomposable quencher (PDQ) group. For example, a repeating unit of the block copolymer may include a salt group that is represented by Formulae (7a) or (7b):

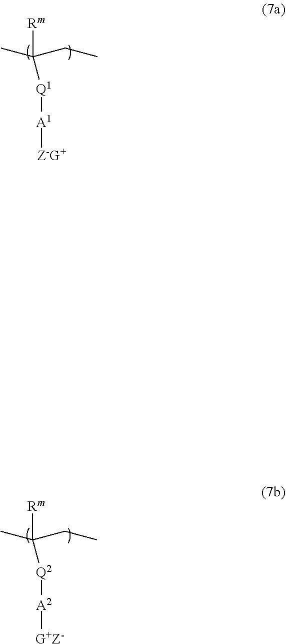

In Formulae (7a) and (7b), each R^{m} may be hydrogen, fluorine, cyano, or substituted or unsubstituted C₁₋₁₀ alkyl. Preferably, R^{m} is hydrogen, fluorine, or substituted or unsubstituted C₁₋₅ alkyl, typically methyl.

In Formulae (7a) and (7b), Q¹ and Q² may be each independently a single bond or a divalent linking group. Preferably, Q¹ and Q² may each independently include 1 to 10 carbon atoms and at least one heteroatom, more preferably —C(O)—O—.

In Formulae (7a) and (7b), A¹ and A² may be each independently one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, or substituted or unsubstituted C₃₋₃₀ heteroarylene. In some embodiments, A¹ and A² may be each independently a divalent C₁₋₃₀ perfluoroalkylene group that is optionally substituted.

In Formula (7a), Z is an anionic moiety that is bonded to A¹, the conjugated acid of which typically has a pKa from −15 to 10. Z may be a sulfonate, a carboxylate, an anion of a sulfonamide, an anion of a sulfonimide, or a methide anion.

In Formula (7a), G⁺ is an organic cation as defined herein. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

In Formula (7b), Z is an anion compound as defined herein, the conjugated acid of which typically has a pKa from −15 to 10. Z⁻ may be a sulfonate, a carboxylate, an anion of a sulfonamide, an anion of a sulfonimide, or a methide anion species. For example, Z⁻ may be as defined herein for the anions A⁻.

In Formula (7b), G⁺ is an organic cation that is bonded to A². For example, G⁺ may include an iodonium cation substituted with two alkyl groups, two aryl groups, or a combination of alkyl and aryl groups; or a sulfonium cation substituted with three alkyl groups, three aryl groups, or a combination of alkyl and aryl groups.

In still other embodiments, when the block copolymer includes a repeating unit having a salt group, the block copolymer may include a zwitterionic species. For example, a block of the block copolymer may include repeating units having a salt group of the Formula (7c):

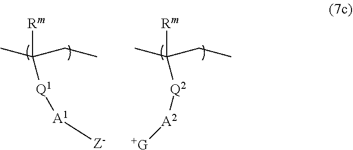

wherein, in Formula (7c), each R™ is independently as defined for Formulae (7a) and (7b).

In Formula (7c), Q¹, A¹, and Z⁻ are as defined in Formula (7a), and Q², A², and G⁺ are as defined in Formula (7b).

Exemplary repeating units of Formula (7a) include the following:

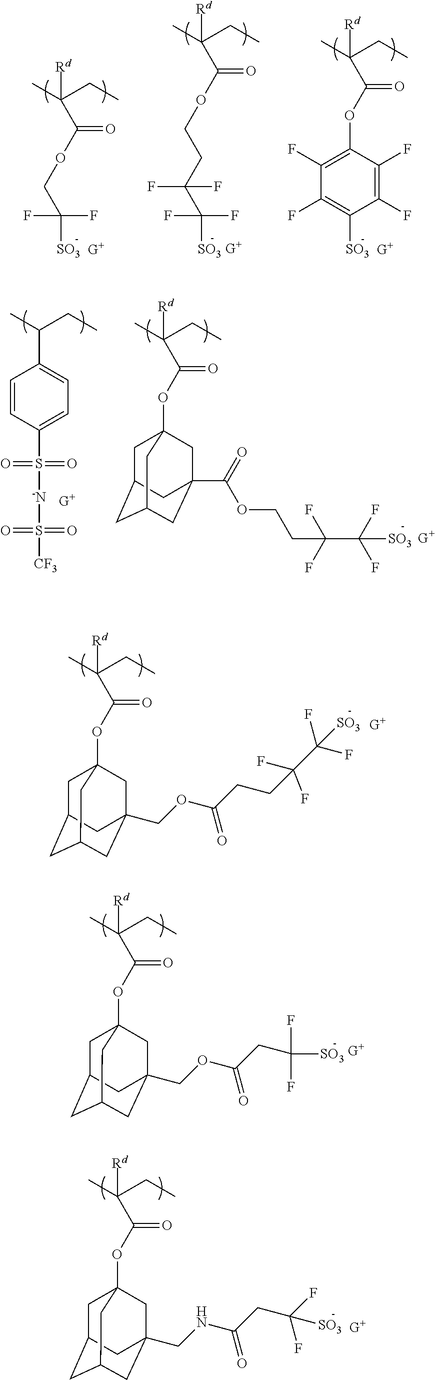

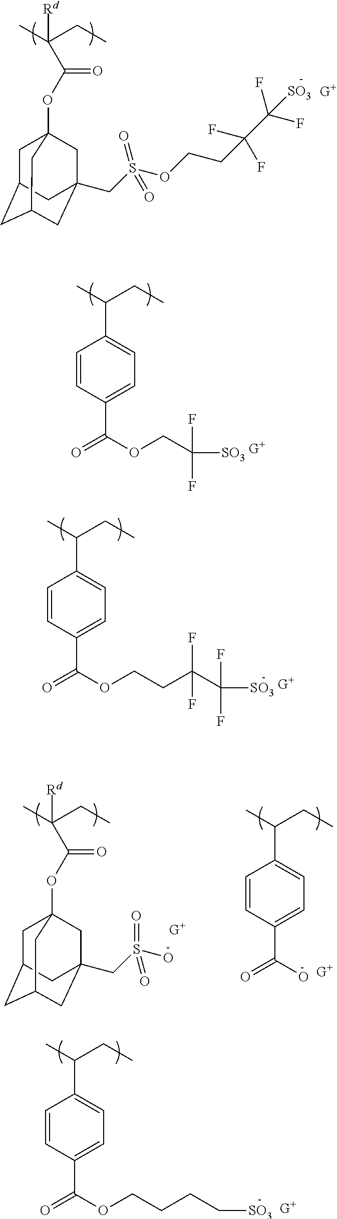

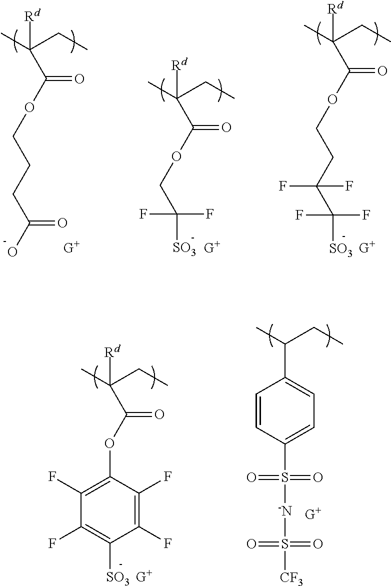

wherein G is the organic cation, and each R^{d} is independently as defined for Formulae (7a).

Exemplary repeating units of Formula (7b) include the following:

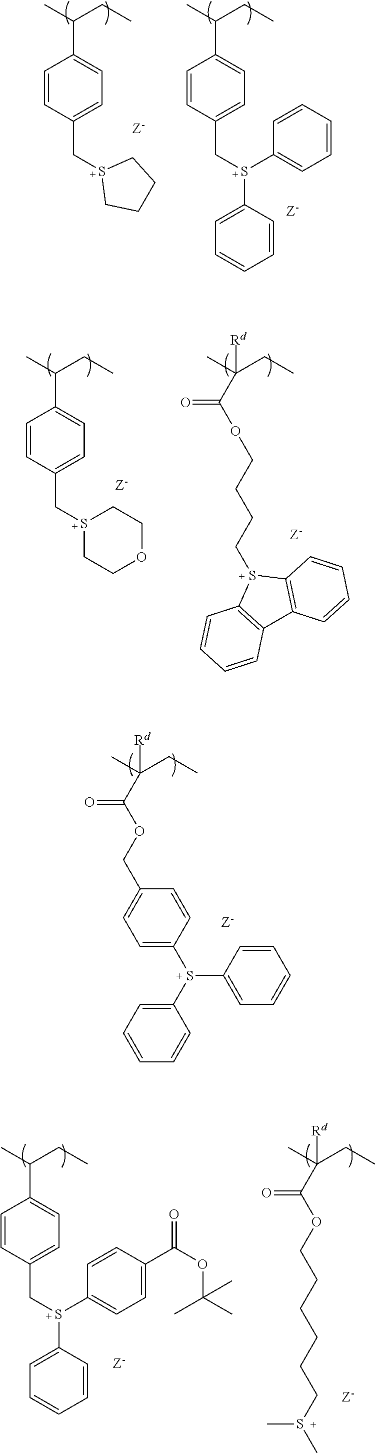

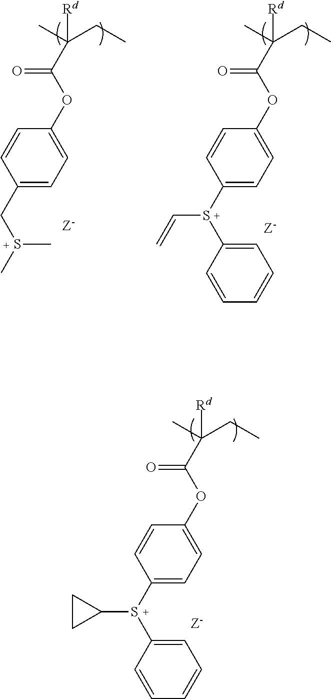

wherein Z is an anion group as defined herein, and each R^{d} is independently as defined for Formulae (7b).

The repeating unit in a block of the block copolymer including a salt typically may be present in an amount from 1 to 35 mol %, typically from 1 to 25 mol %, more typically from 2 to 15 mol %, based on total repeating units of the block. The repeating units including a salt may be present in the block copolymer in an amount from 1 to 35 mol %, typically from 1 to 25 mol %, more typically from 2 to 15 mol %, based on total repeating units of the block copolymer.

A repeating unit of the block copolymer may include a hydroxyaryl group. Exemplary hydroxyaryl groups include a phenolic group or a naphtholic group. For example, a repeating unit of the block copolymer may include a hydroxyaryl group that is represented by Formula (8):

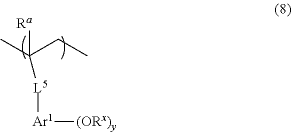

In Formula (8), R^{a} may be hydrogen, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (8), L5 may be a single bond or one or more divalent linking groups. For example, L⁵ may be —O—, —C(O)—, —C(O)O—, —N(R^{c})—, —C(O) N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁵ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (8), Ar¹ may be a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked (such as biaryls, biphenyl, or the like) or may be bridged by a heteroatom (such as triphenylamino or diphenylene ether). In some aspects, the polycyclic C₅₋₆₀ aromatic group may include a combination of fused rings and directly linked rings (such as binaphthyl or the like).

In Formula (8), y may be an integer from 1 to 12, preferably from 1 to 6, and typically from 1 to 3.

In Formula (8), each Rx may independently be hydrogen or methyl, provided that at least one R^{x} is hydrogen.

Non-limiting examples of such repeating units of Formula (8) may include:

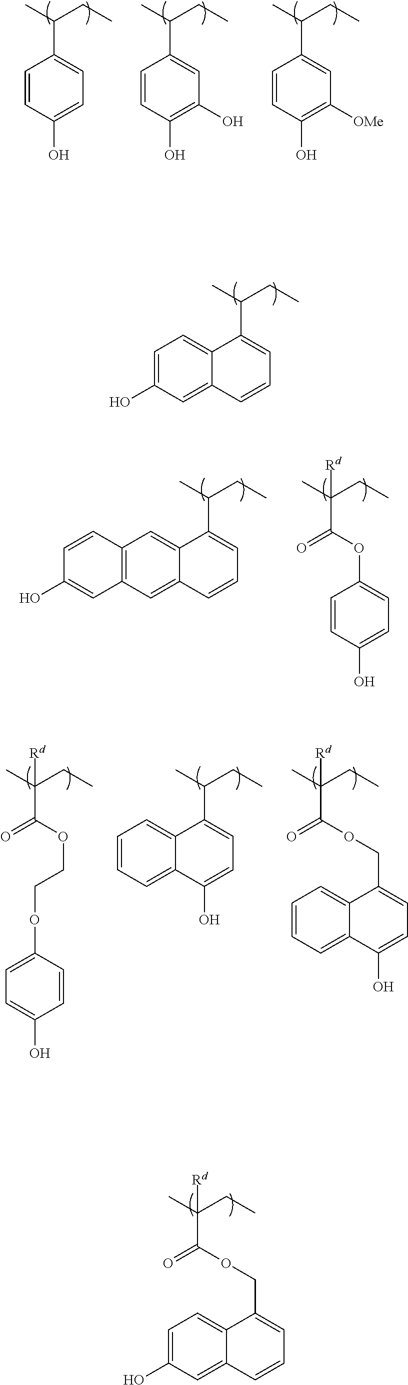

wherein R^{d} may be hydrogen, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit in a block of the block copolymer including a hydroxyaryl group typically may be present in an amount from 10 to 90 mole percent (mol %), more typically from 15 to 75 mol %, and still more typically from 25 to 70 mol %, based on total repeating units of the block. The repeating units including a hydroxyaryl group typically may be present in the block copolymer an amount from 10 to 90 mol %, more typically from 15 to 75 mol %, and still more typically from 25 to 70 mol %, based on total repeating units of the block copolymer.

In some aspects, the blocks of the block copolymer may further optionally include one or more additional repeating units. The additional repeating units may be, for example, one or more additional units for purposes of adjusting properties of the block copolymer. Exemplary additional repeating units may include those derived from one or more of (meth)acrylate, vinyl aromatic, vinyl ether, vinyl ketone, and/or vinyl ester monomers. The one or more additional repeating units, if present in a block of the block copolymer, may be used in an amount of up to 80 mol %, typically from 3 to 50 mol %, based on total repeating units of the block. The one or more additional repeating units, if present, may be used in the block copolymer in an amount of up to 80 mol %, typically from 3 to 50 mol %, based on total repeating units of the block copolymer.

In some embodiments, the block copolymer may include a repeating unit that includes a polar group. Exemplary polar groups include a sultone group, a sulfonamide group, a hydroxyalkyl group, a hydroxycycloalkyl group, or a combination thereof. It is to be understood that some groups, such as a lactone group or a hydroxyaryl group, may be considered to be a polar group, however, these groups are differentiated from the polar groups as used herein.

A repeating unit of the block copolymer may include a polar group that is represented by Formula (9)

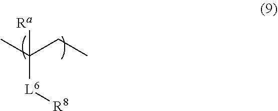

In Formula (9), R^{a} may be hydrogen, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formulae (9), L⁶ may be a single bond or one or more divalent linking groups. For example, L⁶ may be —O—, —C(O)—, —C(O)O—, —N(R^{c})—, —C(O) N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁶ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (9), R⁸ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). The substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of a sulfonamide group (e.g., —NHSO₂CF₃), a hydroxy group (—OH), or a fluoroalcohol group (e.g., —C(CF₃)₂OH).

Non-limiting examples of repeating units of Formula (9) may include:

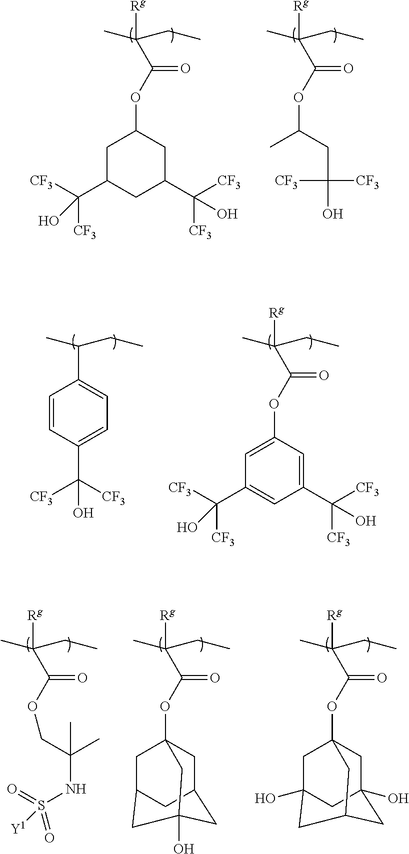

wherein R^{g} may be hydrogen, fluorine, cyano, or substituted or unsubstituted C₁₋₁₀ alkyl. Preferably, R^{g} may be hydrogen, fluorine, or substituted or unsubstituted C₁₋₅ alkyl, typically methyl. Y¹ may be F or C₁₋₄ perfluoroalkyl.

In some embodiments, the block copolymer may include a repeating unit that includes an acid group. Exemplary acid groups include a carboxylic acid group. A repeating unit of the block copolymer may include an acid group that is represented by Formula (10):

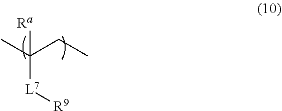

In Formula (10), R^{a} may be hydrogen, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (10), L⁷ may be a single bond or one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₃₋₃₀ heteroarylalkyl, or —C(O)—O—.

In Formula (10), R⁹ may be —C(O)—OH.

Non-limiting examples of repeating units of Formula (10) may include:

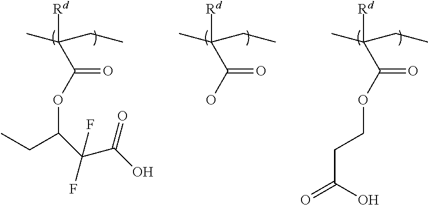

wherein R^{d} may be hydrogen, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit in a block of the block copolymer including an acid group typically may be present in an amount from 1 to 20 mol %, more typically from 5 to 20 mol %, and still more typically from 5 to 10 mol %, based on total repeating units of the block. The repeating units including a hydroxyaryl group typically may be present in the block copolymer an amount from 1 to 20 mol %, more typically from 5 to 20 mol %, and still more typically from 5 to 10 mol %, based on total repeating units of the block copolymer.

Non-limiting exemplary first blocks and second blocks of the block copolymers of the present invention include the following:

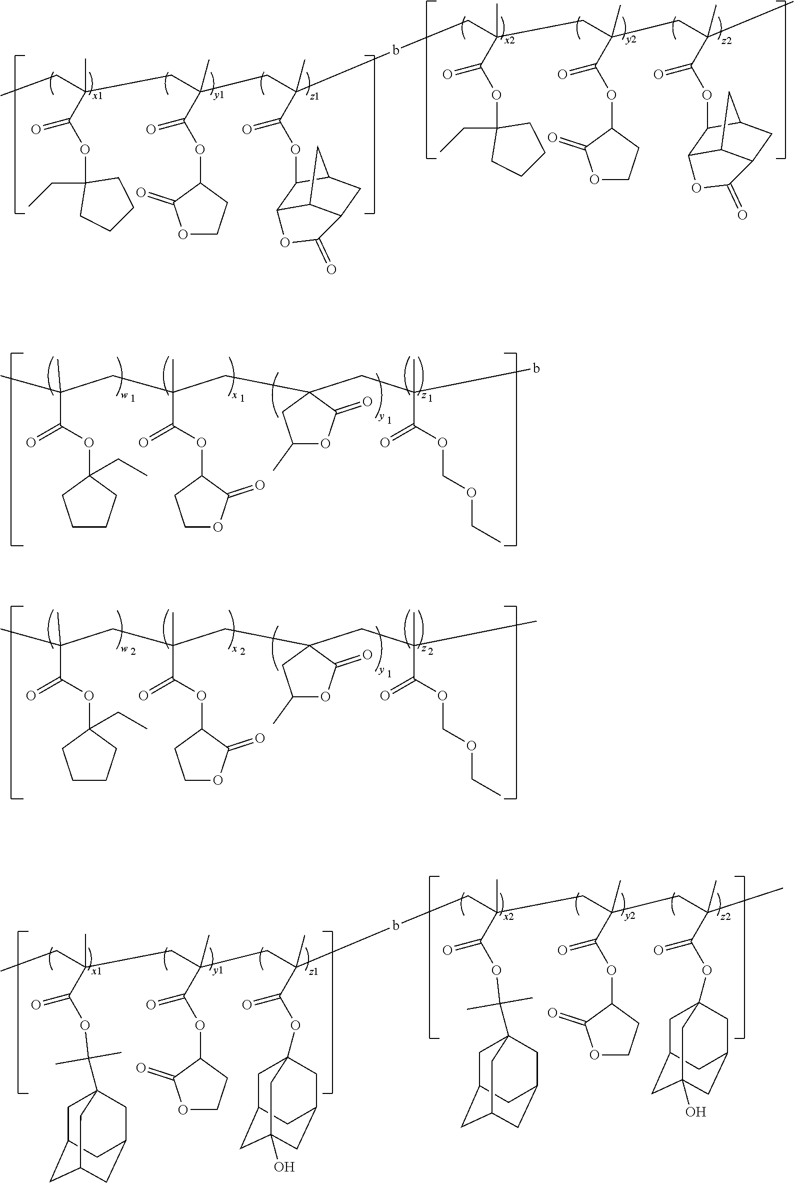

wherein w1, w2, x1, x2, y1, y2, z1, and z2 each represent the mol % of the repeating unit based on 100 mol % of total repeating units in the block of the block copolymer.

In the block copolymers, an average number of repeating units within each block may be 5 or more. Typically, the average number of polymerized units within each block may be 10 or more, or 20 or more, or 100 or more. For example, a triblock copolymer that includes three blocks can have 15 or more, or 30 or more, or 75 or more, or 150 or more total repeating units.

In the block copolymers, an average number of blocks in the block copolymer may be from 3 to 10. Typically, the block copolymer may have an average number of blocks that is from 3 to 5.

The block copolymer typically has a weight average molecular weight (M_{w}) from 2,500 to 50,000 grams per mole (g/mol), preferably from 2,500 to 30,000 g/mol, more preferably 2,500 to 20,000 g/mol, and still more preferably from 2,500 to 15,000 g/mol. The dispersity index (D) of the block copolymer, which is the ratio of M_{w} to Mₙ, is typically from 1.1 to 3, more typically from 1.1 to 2, and preferably from 1.1 to 1.7, 1.1 to 1.6, or 1.1 to 1.5 (Mₙ is number average molecular weight). Molecular weights are determined by gel permeation chromatography (GPC) using polystyrene standards.

Also provided is a block copolymer that includes a plurality of block copolymers as described herein, wherein each of the block copolymers of the plurality of block copolymers is different. That is, an aspect provides a block copolymer that is derived from a plurality of the block copolymers as described herein, where each of the block copolymers of the plurality of block copolymers is different. For example, such a block copolymer may include a first segment derived from a first block copolymer having a first gradient of repeating units, and a second segment derived from a second block copolymer having a second gradient of repeating units, where the first gradient of repeating units and the second gradient of repeating units are different.

Another aspect provides a polymer that includes one or more block copolymers, where the block copolymers are bonded to another part of the polymer. In other words, in some aspects, the block copolymers described herein may be bonded (e.g., grafted) to another polymer using any suitable method.

The block copolymer may be prepared using any suitable method(s) in the art. For example, one or more monomers corresponding to the polymerized units described herein may be combined, or fed separately, using suitable solvent(s) and initiator, and polymerized in a reactor. For example, the block copolymer may be obtained by polymerization of the respective monomers under any suitable conditions, such as by heating at an effective temperature, irradiation with actinic radiation at an effective wavelength, or a combination thereof.

Each monomer corresponding to the repeating units described herein independently comprises a polymerizable group having a carbon-carbon unsaturated vinylic group, and typically may be selected from a substituted or unsubstituted C₂₋₂₀ alkenyl group, a substituted or unsubstituted norbornyl group, a substituted or unsubstituted(meth)acrylic group, a substituted or unsubstituted vinyl ether group, a substituted or unsubstituted vinyl ketone group, a substituted or unsubstituted vinyl ester group, or a substituted or unsubstituted vinyl aromatic group. Typically, the polymerizable group of each monomer is independently substituted or unsubstituted C₂₋₂₀ alkenyl, substituted or unsubstituted norbornyl, substituted or unsubstituted(meth)acrylic, or substituted or unsubstituted vinyl aromatic. Preferably, the polymerizable group of each monomer is independently substituted or unsubstituted(meth)acrylic, or substituted or unsubstituted vinyl aromatic.

The block copolymers can be prepared using living or controlled free radical polymerization techniques, including reversible addition fragmentation chain transfer polymerization (RAFT), nitroxide mediated polymerization (NMP), atom transfer radical polymerization (ATRP), or the like. Unlike controlled free radical polymerization, conventional free radical polymerization often proceeds at a relatively uncontrolled rate until exhaustion of monomer reactant(s). Average molecular weight could be generally controlled by controlling initiator loading, monomer loading, initiation rate, termination rate, and propagation rate; however, due to the difficulty of controlling precisely when the chain-terminating reaction might occur on any individual macroradical chain, conventional free radical polymerization could result in a wide range of polymer chain lengths in the population of polymer molecules, resulting in a highly polydisperse copolymer. Controlled free radical polymerization occurs when the side reactions that lead to termination of the polymer chain are eliminated or significantly reduced, and the degree of polymerization is manipulated by controlling the equilibrium of a reversible transformation of the living polymer chain between an active form macroradical that will propagate chain growth and an inactive or dormant macromolecule that cannot propagate chain growth unless it is converted into the active macroradical form. Controlled free radical polymerization is thus able to produce block copolymers through free radical chain extension where molecular weight is readily controlled and with improved lower polydispersities.

The polymerization may use chain transfer agents (CTAs) including thiocarbonylthio compounds, such as dithioesters, thiocarbamates, xanthates, or the like, to mediate the polymerization via a reversible chain-transfer process. In some embodiments, the block copolymer may be produced by reacting the selected monomer(s) with a dithioester chain transfer agent and an initiator to produce the block copolymer. In some embodiments, the initiator may be light.

Exemplary chain transfer agents (CTAs) for controlled free radical polymerization include thiocarbonylthio compounds, such as 2-cyano-2-propyl benzodithioate, 4-cyano-4-(phenylcarbonothioylthio) pentanoic acid, 2-cyano-2-propyl dodecyl trithiocarbonate, 4-cyano-4-[(dodecylsulfanylthiocarbonyl) sulfanyl]pentanoic acid, 2-(dodecylthiocarbonothioylthio)-2-methylpropionic acid, cyanomethyl dodecyl trithiocarbonate, cyanomethyl methyl(phenyl) carbamodithioate, bis(thiobenzoyl)disulfide, bis(dodecylsulfanyl-thiocarbonyl)disulfide, or the like.

Examples of initiators include azobis(isobutyronitrile)(AIBN), azobis(2-methylbutyronitrile), azobis(2,4-dimethylvaleronitrile), azobis(4-cyanovaleric acid). Examples of peroxide and peroxy initiators include hydrogen peroxide, sodium peroxide, potassium peroxide, t-butyl hydroperoxide, cumene hydroperoxide, dilauroyl peroxide, tert-butyl peroxyneodecanoate, dibenzoyl peroxide, cumyl peroxide, tert-butyl peroxy-2-ethyl hexanoate, tert-butyl peroxy diethyl acetate and tert-butyl peroxy benzoate. Examples of additional initiators include ammonium and/or alkali metal persulfates, sodium perborate, perphosphoric acid and salts thereof, potassium permanganate, and ammonium or alkali metal salts of peroxydisulfuric acid, examples being alkali metal or ammonium peroxydisulfates, diacetyl peroxide, dibenzoyl peroxide, succinyl peroxide, di-tert-butyl peroxide, tert-butyl perbenzoate, tert-butyl perpivalate, tort-butyl peroxy-2-ethylhexanoate, tert-butyl permaleinate, cumene hydroperoxide, diisopropyl peroxydicarbamate, bis(o-toluoyl) peroxide, didecanoyl peroxide, dioctanoyl peroxide, dilauroyl peroxide, tert-butyl perisobutyrate, tert-butyl peracetate, di-tert-amyl peroxide, tert-butyl hydroperoxide, azobisisobutyronitrile, 2,2′-azobis(2-amidino-propane) dihydrochloride or 2,2′-azobis(2-methylbutyronitrile). Also suitable are mixtures of these initiators. As initiators it is also possible to use reduction/oxidation (i.e., redox) initiator systems. The redox initiator systems are composed of at least one, usually inorganic, reducing agent and one organic or inorganic oxidizing agent. The oxidizing component comprises, for example, the polymerization initiators already specified above. The reducing component comprises, for example, alkali metal salts of sulfurous acid, such as sodium sulfite, sodium hydrogen sulfite, alkali metal salts of disulfurous acid such as sodium disulfite, bisulfite addition compounds of aliphatic aldehydes and ketones, such as acetone bisulfite or reducing agents such as hydroxymethanesulfinic acid and salts thereof, or ascorbic acid. The redox initiator systems can be used along with soluble metal compounds whose metallic component is able to occur in a plurality of valence states. Typical redox initiator systems are, for example, ascorbic acid/iron (II) sulfate/sodium peroxodisulfate, tert-butyl hydroperoxide/sodium disulfite, tert-butyl hydroperoxide/Na hydroxymethanesulfinate. The individual components, the reducing component for example, may also be mixtures, an example being a mixture of the sodium salt of hydroxymethanesulfinic acid and sodium disulfite.

Nitroxide mediated polymerization, or NMP, which uses stable nitroxide radicals or alkoxyamines as initiators, can also be used to prepare the block copolymers. Examples of suitable initiators for NMP include N-tert-butyl-N-(2-methyl-1-phenylpropyl)-O-(1-phenylethyl) hydroxylamine, N-tert-butyl-O-[1-[4-(chloromethyl)phenyl]ethyl]-N-(2-methyl-1-phenylpropyl) hydroxylamine, 2,2,5-trimethyl-4-phenyl-3-azahexane-3-nitroxide, 2,2,6,6-tetramethyl-1-piperidinyloxy (TEMPO), or the like.

The block copolymers can also be prepared using atom transfer radical polymerization, or ATRP. Suitable initiators for ATRP include tert-butyl a-bromoisobutyrate, a-bromoisobutyryl bromide, dodecyl 2-bromoisobutyrate, ethyl a-bromoisobutyrate, methyl a-bromoisobutyrate, octadecyl 2-bromoisobutyrate, or the like. Suitable catalysis for ATRP include copper (I) chloride, copper (II) chloride, copper (I) bromide, copper (II) bromide, copper (I) iodide, and the like. Suitable ligands for ATRP include tris(2-pyridylmethyl)amine, tris [2-(dimethylamino)ethyl]amine, 4,4′-dinonyl-2,2′-dipyridyl, N,N,N′,N″,N″-pentamethyldiethylenetriamine, or the like.

The initiator may be used in molar ratio from 0.05 to 2 with respect to the chain transfer agent. In an exemplary embodiment, the initiator may be used in molar ratio from 0.07 to 1 with respect to the chain transfer agent.

The amount of initiator is generally at least 0.01 or 0.05 or 0.01 wt % to 10, or 5 or 3 wt % based on all of the monomers to be polymerized.

The polymerization reactions used to prepare the block copolymers may be performed in any suitable solvent, although the polymerization may also proceed in the absence of a solvent. Exemplary polymerization solvents include ethers, cyclic ethers, C₅₋₁₀ alkanes, C₅₋₈ cycloalkanes which may be substituted with from 1 to 3 C₁₋₄ alkyl groups, aromatic hydrocarbon solvents, halogenated hydrocarbon solvents, acetonitrile, dimethylformamide, ethylene carbonate, propylene carbonate, dimethylsulfoxide, dimethylsulfone, water, mixtures of such solvents, supercritical solvents (such as CO₂, C₁₋₄ alkanes in which any H may be replaced with F, or the like), or a combination thereof.

A typical procedure to prepare the block copolymers is as follows. A mixture of monomers is typically prepared in a solvent and combined with an initiator. The solution may be degassed with nitrogen and taken into a syringe as a feed mixture. Portions of the feed mixture may then be added to a heated reaction vessel that includes a chain transfer agent, and the polymerization may be allowed to proceed for a period of time to form a first block of the block copolymer. Subsequently, a second portion of the feed mixture may be added to the heated reaction vessel and the polymerization may be allowed to proceed for a period of time to form a second block of the block copolymer. Additional blocks of the copolymer may be formed using a similar sequence of steps. Although the example described above provides for a single feed mixture, wherein the ratio of monomers remains constant for each subsequently formed block of the block copolymer, in other embodiments a different feed mixture may be added at each step to vary the ratio of the monomers used to prepare each block of the block copolymer. For block copolymers that include additional blocks beyond the first block and the second block as described herein, different feed mixtures may be used to form the third block and subsequent blocks, such that each block may have the same or different monomer compositions and/or ratios.

After the polymerization is complete, the formed block copolymer is isolated. The isolating step may be conducted by known procedures, and may include evaporating any residual monomer and/or solvent, precipitating in a suitable solvent, filtering or centrifuging the precipitated block copolymer, washing the block copolymer, and drying the washed block copolymer. Transition metal compounds may be removed by passing through a column or a pad of alumina, silica, and/or clay. Alternatively, transition metal compounds may be oxidized (if necessary) and retained in the block copolymer as a stabilizer. The chain terminating groups, when present, may be cleaved from the block copolymers using any suitable methods known in the art.

Precipitation can be typically conducted using a suitable C₅₋₈ alkane or C₅₋₈ cycloalkane solvent, such as pentane, hexane, heptane, cyclohexane, or mineral spirits, or using a C₁₋₆ alcohol, such as methanol, ethanol, or isopropanol, or a combination of suitable solvents.

Also provided is a photoresist composition including the block copolymer as described herein, and a solvent. In some embodiments, the photoresist composition may include the block copolymer as described herein, a photoacid generator, and a solvent. In still other embodiments, the photoresist composition may include a first polymer that is the block copolymer as described herein, a photoacid generator, and a solvent, and may further include a second (different) polymer that is structurally different from the first polymer (the block copolymer).

The second polymer may include one or more polymerized (e.g., repeating) units, such as those described herein. Exemplary second polymer may be polyacrylates, polyvinylethers, polyesters, polynorbornenes, polyacetals, polyethylene glycols, polyamides, polyacrylamides, polyphenols, novolacs, styrenic polymers, polyvinyl alcohols, or a combination thereof. For example, the second polymer may include a repeating unit that includes an acid labile group, a hydroxyaryl group, a fluoroalcohol group, a sulfonamide group, a lactone group, or a combination thereof.

The second polymer typically has a M_{w} from 1,000 to 50,000 g/mol, specifically from 2,000 to 30,000 g/mol, more specifically from 3,000 to 20,000 g/mol, still more specifically from 3,000 to 10,000 g/mol. The PDI of the polymer, which is the ratio of M_{w} to Mₙ is typically from 1.1 to 3, and specifically from 1.1 to 2. Molecular weights are determined by GPC using polystyrene standards.

The second polymer may be prepared using any suitable methods in the art. For example, one or more monomers corresponding to the polymerized units described herein may be combined, or fed separately, using suitable solvent(s) and initiator, and polymerized in a reactor. For example, the second polymer may be obtained by polymerization of the respective monomers under any suitable conditions, such as by heating at an effective temperature, irradiation with actinic radiation at an effective wavelength, or a combination thereof.

The photoresist composition includes a solvent for dissolving the components of the composition and facilitating its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof. The total solvent content (i.e., cumulative solvent content for all solvents) in the photoresist composition is typically from 40 to 99 weight percent (wt %), more typically from 70 to 99 wt %, and still more typically from 85 to 99 wt %, based on total weight of the photoresist composition. The desired solvent content will depend, for example, on the desired thickness of the coated photoresist layer and coating conditions.

In the photoresist compositions, the block copolymer typically may be present in the photoresist composition in an amount from 10 to 99.9 wt %, typically from 25 to 99 wt %, and more typically from 50 to 95 wt %, based on total solids of the photoresist composition. It will be understood that total solids includes the block copolymer, PAG(s), and other non-solvent components.

The photoresist composition may further include a photoacid generator (PAG). The PAG may be in ionic or non-ionic form. The PAG may be in polymeric or non-polymeric form. In polymeric form, the PAG may be present as a moiety in a repeating unit of a polymer that is derived from a polymerizable PAG monomer. In some embodiments, the block copolymer may further include a repeating unit that includes a PAG functionality (e.g., as a salt group of a repeating unit).

Suitable PAG compounds may be of the formula G⁺A⁻, wherein G⁺ is a photoactive cation and A is an anion that can generate a photoacid. The PAG cation is preferably chosen from onium cations, preferably iodonium or sulfonium cations. Particularly suitable anions include those whose conjugated acids have a pKa from −15 to 10. The PAG anion is typically an organic anion having a sulfonate group or a non-sulfonate-type group, such as sulfonamidate, sulfonimidate, methide, or borate.

In some embodiments, the PAG cation may be a sulfonium cation or an iodonium cation. For example, the PAG cation may be a sulfonium cation of Formula (10) or an iodonium cation of Formula (11):

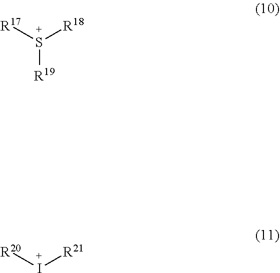

In Formulae (10) and (11), R¹⁷ to R²¹ may each independently be substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₆₋₃₀ iodoaryl, substituted or unsubstituted C₃₋₃₀ heteroaryl, substituted or unsubstituted C₇₋₂₀ arylalkyl, or substituted or unsubstituted C₄₋₂₀ heteroarylalkyl, or combinations thereof. Each of R¹⁷ to R¹⁹ may be either separate or connected to another group of R¹⁷ to R¹⁹ via a single bond or a divalent linking group to form a ring. R²⁰ and R²¹ may be either separate or connected to each other via a single bond or a divalent linking group to form a ring. Each of R¹⁷ to R²¹ optionally may include as part of its structure a divalent linking group. Each of R¹⁷ to R²¹ independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of Formula (10) may include one or more of the following:

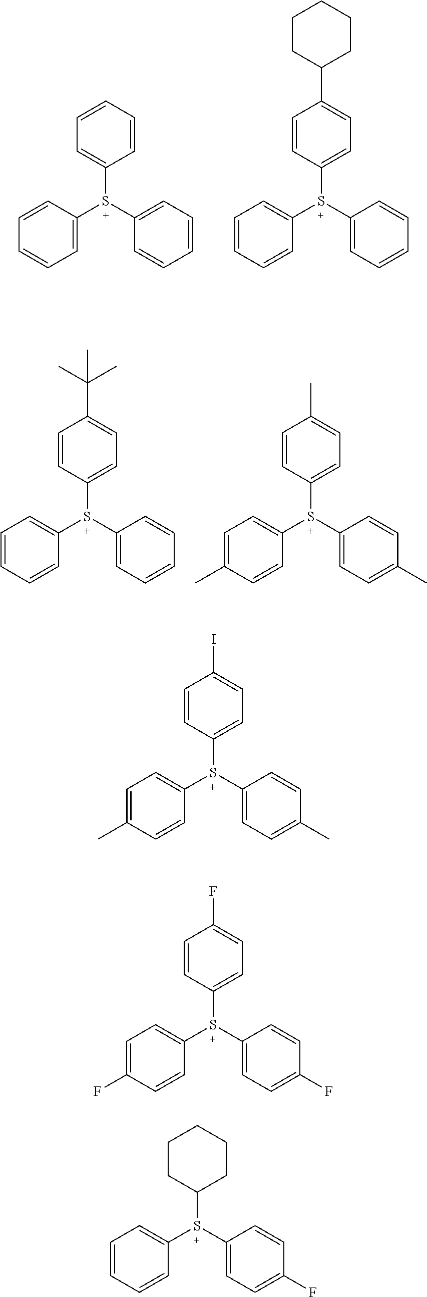

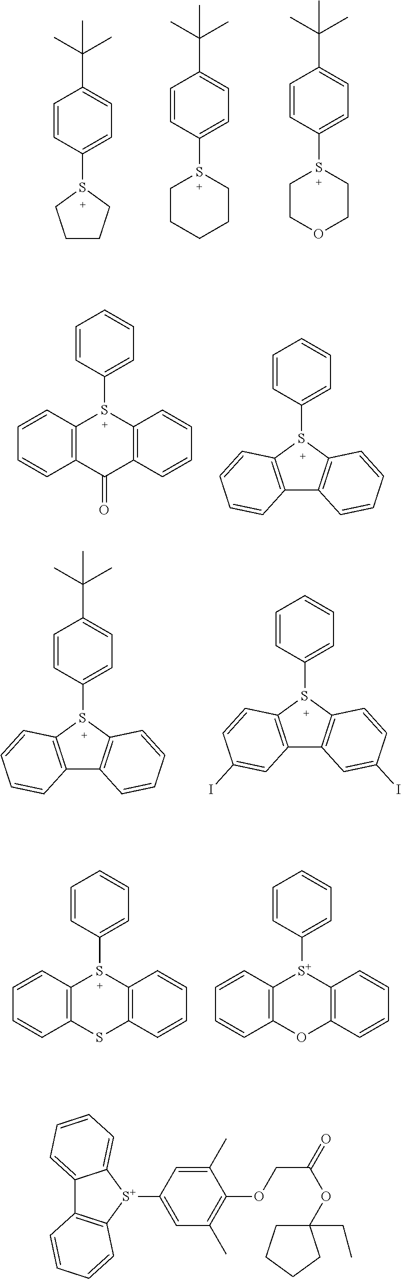

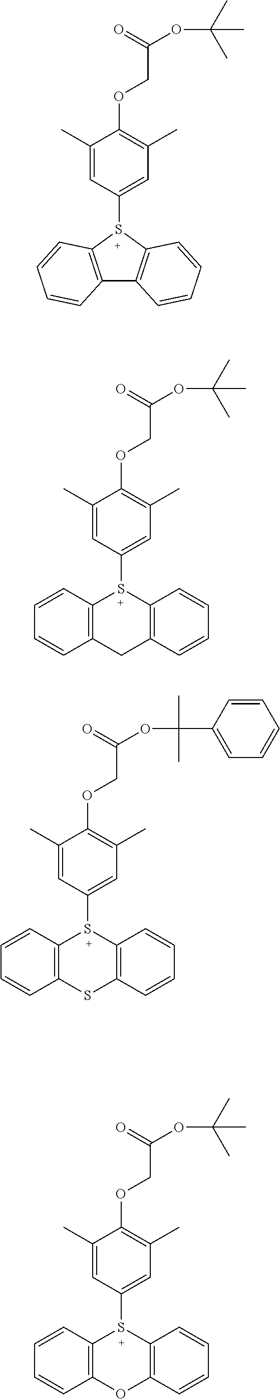

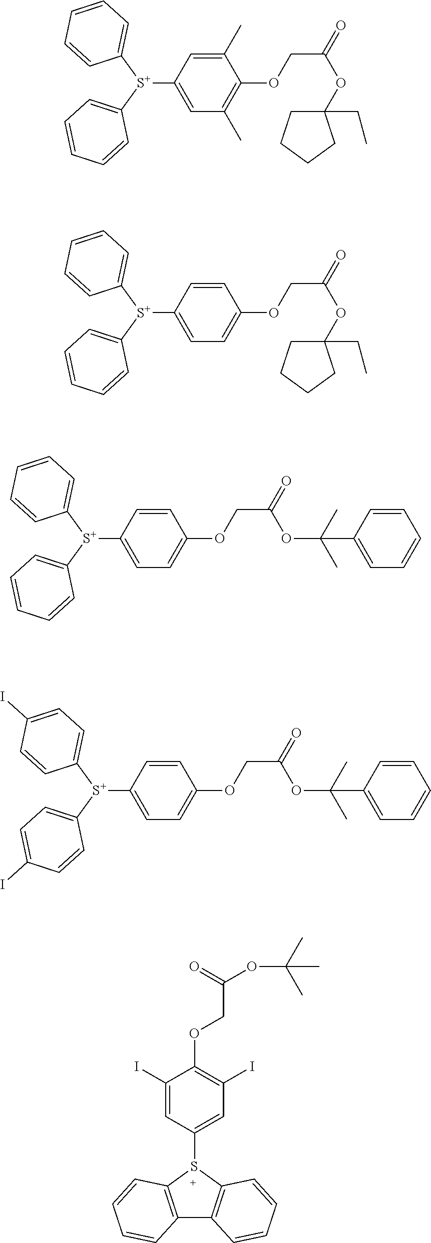

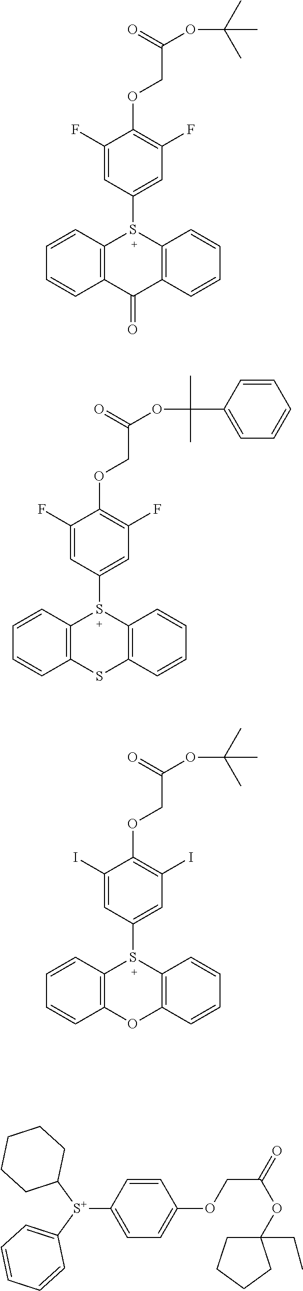

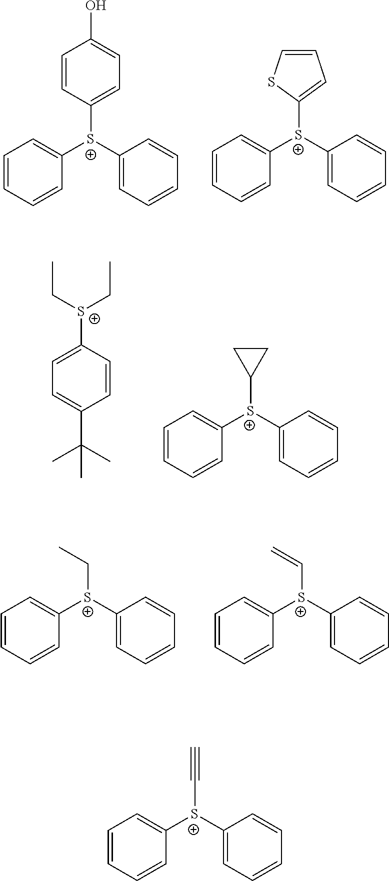

Exemplary iodonium cations of Formula (11) may include one or more of the following:

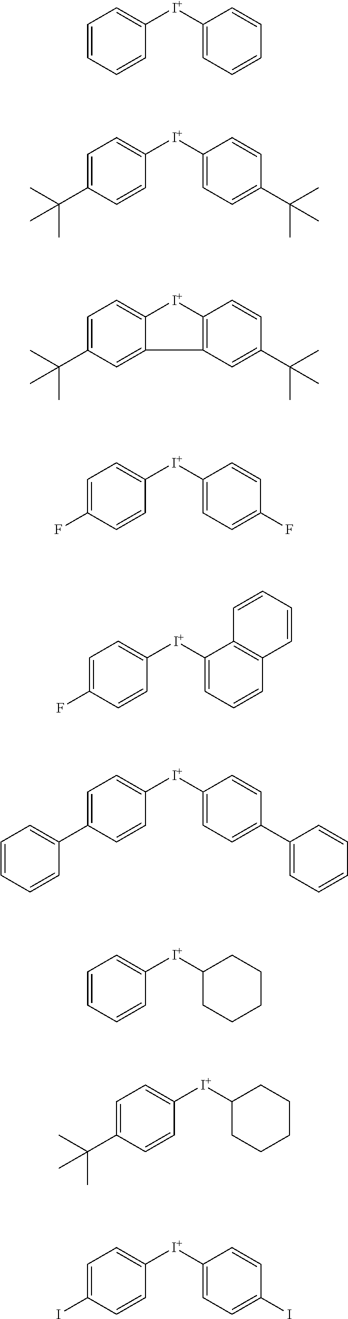

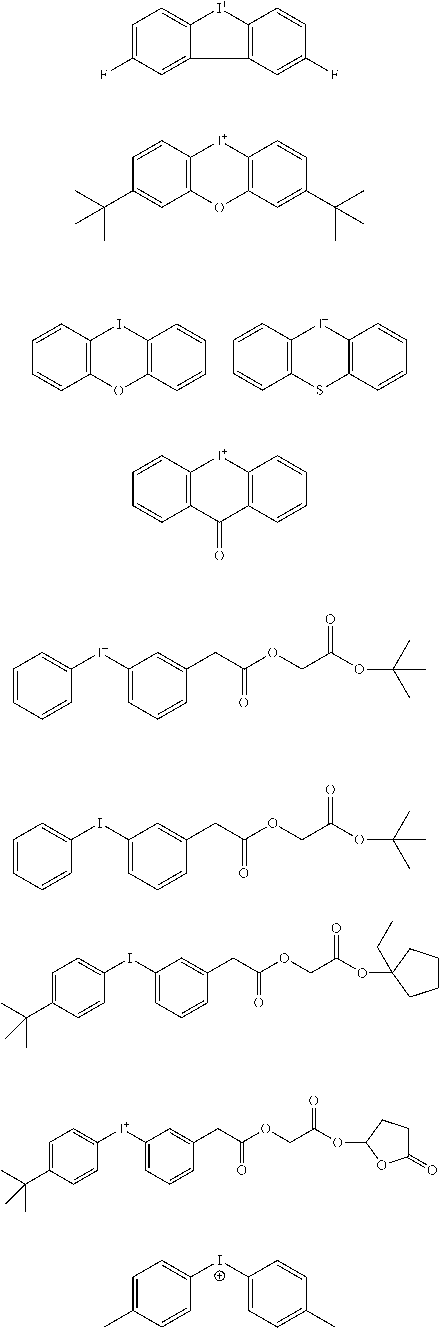

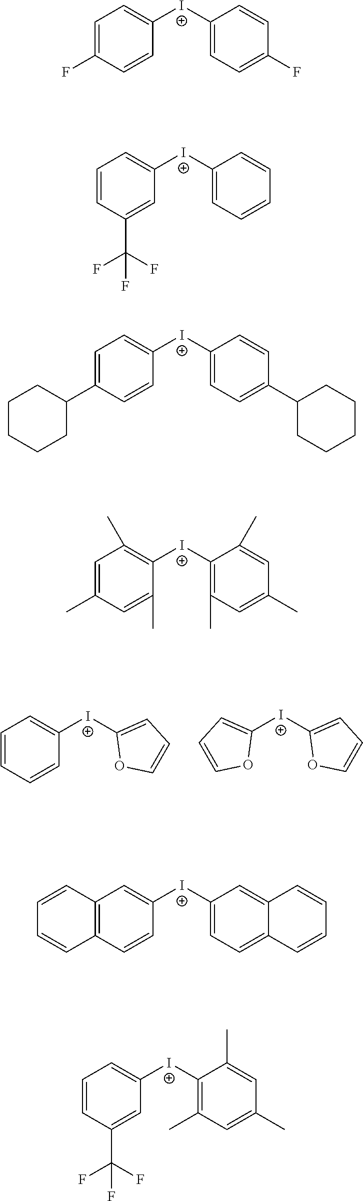

Exemplary organic anions having a sulfonate group may include one or more of the following:

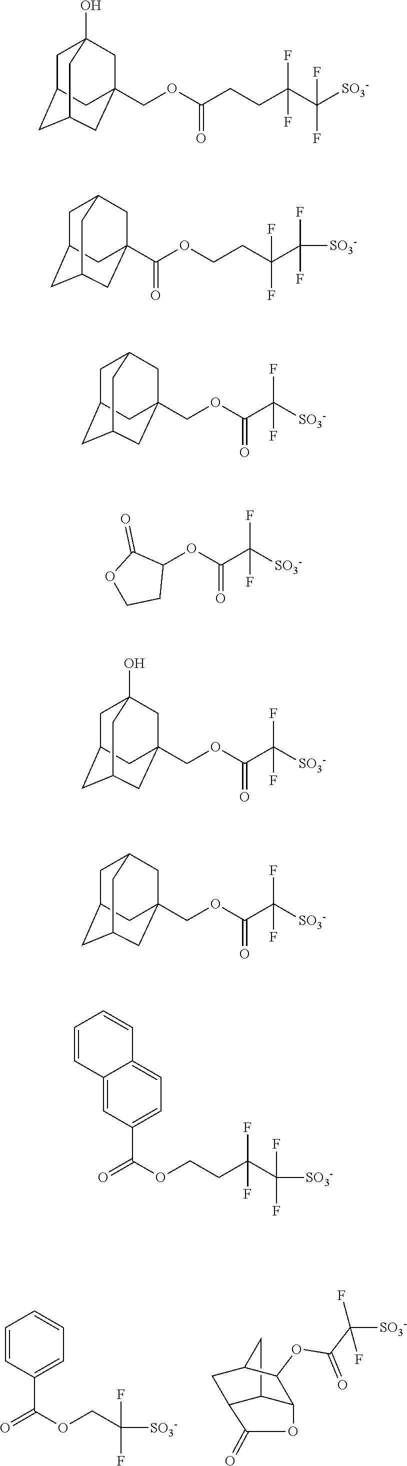

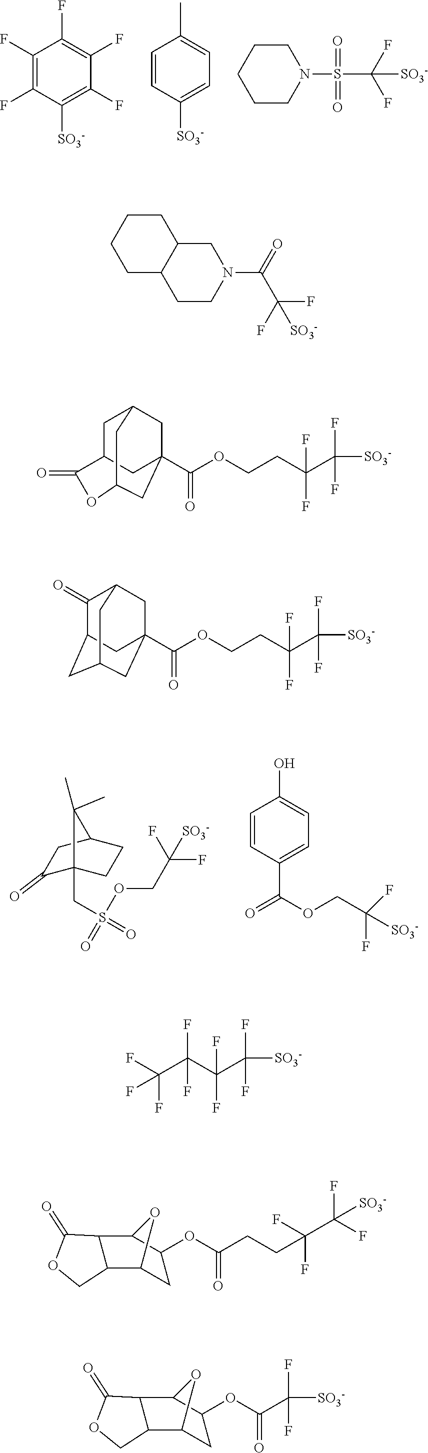

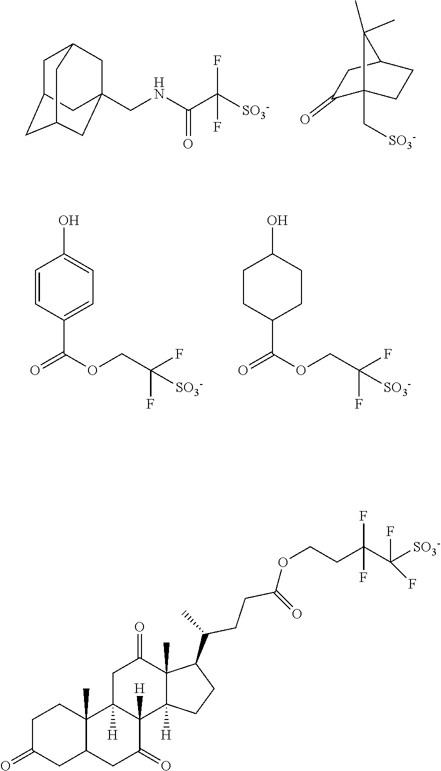

Exemplary non-sulfonated anions may include one or more of the following:

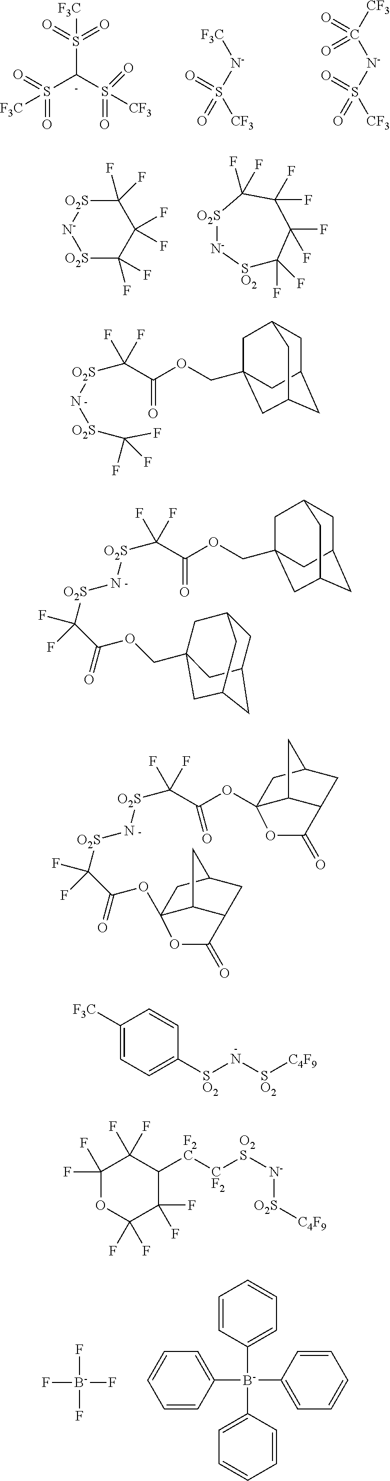

Commonly used onium salts may include, for example, triphenylsulfonium trifluoromethanesulfonate, (p-tert-butoxyphenyl)diphenylsulfonium trifluoromethanesulfonate, tris(p-tert-butoxyphenyl) sulfonium trifluoromethanesulfonate, triphenylsulfonium p-toluenesulfonate; di-t-butyphenyliodonium perfluorobutanesulfonate, and di-t-butyphenyliodonium camphorsulfonate. Other useful PAG compounds are known in the art of chemically amplified photoresists and include, for example: non-ionic sulfonyl compounds, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy) benzene, and 1,2,3-tris(p-toluenesulfonyloxy) benzene; diazomethane derivatives, for example, bis(benzenesulfonyl)diazomethane, bis(p-toluenesulfonyl) diazomethane; glyoxime derivatives, for example, bis-O-(p-toluenesulfonyl)-a-dimethylglyoxime, and bis-O-(n-butanesulfonyl)-a-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. Nos. 8,431,325 and 4,189,323.

Typically, when the photoresist composition includes a non-polymeric PAG, the PAG is present in the photoresist composition in an amount from 0.1 to 55 wt %, more typically from 1 to 25 wt %, based on total solids of the photoresist composition. When present in polymeric form, the PAG is typically included in a polymer in an amount from 1 to 25 mol %, more typically from 1 to 20 mol %, or from 2 to 10 mol %, based on total polymerized units in the polymer.

In some aspects, the anion and/or cation of the PAG does not include and is free of —F, —CF₃, or —CF₂-groups. It should be understood that “free of —F, —CF₃, or —CF₂-groups” means that the anion and/or cation of the PAG excludes groups such as —CH₂CF₃ and —CH₂CF₂CH₃. In still other aspects, the anion and/or the cation of the PAG is free of fluorine (i.e., does not contain a fluorine atom and is not substituted by a fluorine-containing group). In some aspects, the photoacid generator is free of fluorine (i.e., both the photoactive cation and the anion are free of fluorine).

In some aspects, the photoresist composition may further include a surface-active material. Preferably, the surface-active material is hydrophobic, and is substantially not miscible with and has a lower surface energy than the block copolymer and other solid components of the photoresist composition. When coated on a substrate, the surface-active material can thereby segregate from other solid components of the photoresist composition to a top surface of the formed photoresist layer. The surface-active material can provide beneficial surface properties to the photoresist composition when coated on a substrate. For example, in an immersion exposure process, the surface-active material can function as a barrier layer between the immersion fluid, typically water, that is interposed between the lens of the exposure tool and the photoresist layer. This can minimize or prevent leaching of components of the underlying portion of the photoresist into the immersion fluid that could otherwise cause contamination of the lens and alter the effective refractive index and transmission properties of the immersion fluid. Due to its hydrophobic nature, the surface-active material can allow for a high receding contact angle with respect to the immersion fluid, which can allow for faster scanning speeds and increased process throughput. In immersion and non-immersion exposure processes, the surface-active material can also have a beneficial impact on reducing defectivity, for example, patterning defects such as closed contacts and bridging defects in line-space patterns.

The surface-active material is preferably soluble in the developer or becomes soluble in the developer during patterning such as by interaction with a generated photoacid or with the developer. In some aspects, the surface-active material may be a polymeric material. The surface-active material can be a homopolymer or a copolymer comprising two, three, or more different types of repeat units. In some aspects, the surface-acting material may be non-polymeric, in the form of a single molecule. Suitable for the surface-active materials include, for example, one or more groups chosen from acid groups such as carboxylic acid or sulfonic acid groups, acid-labile groups, base-labile groups, base-soluble groups such as fluoroalcohol or phenol groups, alkyl groups, fluoroalkyl groups, ester groups, and combinations thereof. In the case of an aqueous base developer such as a 0.26 normal (N) aqueous solution of tetramethylammonium hydroxide (TMAH), the surface-active polymer preferably includes one or more base-labile or base soluble groups to enhance the solubility in the developer solution after exposure to activating radiation and post-exposure baking.

When present, the surface-active material is typically present in the photoresist compositions in an amount from 0.01 to 10 wt %, typically from 1 to 5 wt %, based on total solids of the photoresist composition.

The photoresist composition may further include one or more additional, optional additives. For example, optional additives may include actinic and contrast dyes, anti-striation agents, plasticizers, speed enhancers, sensitizers, photo-decomposable quenchers (PDQ)(and, also known as photo-decomposable bases), basic quenchers, thermal acid generators, surfactants, and the like, or combinations thereof. If present, the optional additives are typically present in the photoresist compositions in an amount from 0.01 to 10 wt %, based on total solids of the photoresist composition.

PDQs generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

The PDQ may be in non-polymeric or polymer-bound form. The polymerized units containing the photo-decomposable quencher are typically present in an amount from 0.1 to 30 mol %, preferably from 1 to 10 mol % and more preferably from 1 to 2 mol %, based on total repeating units of the polymer.

Exemplary basic quenchers include, for example, linear aliphatic amines such as tributylamine, trioctylamine, triisopropanolamine, tetrakis(2-hydroxypropyl)ethylenediamine: n-tert-butyldiethanolamine, tris(2-acetoxy-ethyl)amine, 2,2′,2″,2′″-(ethane-1,2-diylbis(azanetriyl)) tetraethanol, 2-(dibutylamino) ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl) morpholine; aromatic amines such as pyridine, di-tert-butyl pyridine, and pyridinium; linear and cyclic amides and derivatives thereof such as N,N-bis(2-hydroxyethyl) pivalamide, N,N-diethylacetamide, N1,N1,N3,N3-tetrabutylmalonamide, 1-methylazepan-2-one, 1-allylazepan-2-one, and tert-butyl 1,3-dihydroxy-2-(hydroxymethyl) propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount from 0.1 to 30 mol %, preferably from 1 to 10 mol % and more preferably from 1 to 2 mol %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants (3M Corporation); and fluorodiols such as POLYFOX™ PF-636, PF-6320, PF-656, and PF-6520 fluorosurfactants (Omnova). In an aspect, the photoresist composition further includes a surfactant polymer including a fluorine-containing repeating unit.

Also provided are methods of forming a pattern. According to an aspect, a method of forming a pattern includes applying a layer of a photoresist composition on a substrate to form a photoresist composition layer; pattern-wise exposing the photoresist composition layer to activating radiation to form an exposed photoresist composition layer; and developing the exposed photoresist composition layer to provide a resist relief image. The photoresist composition includes the block copolymer as described herein and a solvent.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from DuPont Electronics & Industrial (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, from 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the total solids of the composition. A photoresist composition layer formed from the compositions of the invention typically has a dried layer thickness from 3 to 30 micrometers (μm), preferably from greater than 5 to 30 μm, and more preferably from 6 to 25 μm.

The photoresist composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the photoresist composition and thickness. The soft bake temperature is typically from 80 to 170° C., and more typically from 90 to 150° C. The soft bake time is typically from 10 seconds to 20 minutes (mins.), more typically from 1 to 10 mins., and still more typically from 1 to 2 mins. The heating time can be readily determined by one of ordinary skill in the art based on the components of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nanometer (nm), sub-300 nm or sub-200 nm, with 248 nm (KrF), 193 nm (ArF), 13.5 nm (EUV) wavelengths or e-beam lithography being preferred. Preferably, the activating radiation is 193 nm radiation or EUV wavelengths. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time from 5 to 60 seconds being typical. Development is typically conducted at room temperature.

Suitable developers for a PTD process include aqueous base developers, for example, quaternary ammonium hydroxide solutions such as TMAH, preferably 0.26 N TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### Examples

### Synthesis Examples

The synthetic reactions were performed under a nitrogen atmosphere. Dimethyl 2,2′-azobis(2-methylpropionate)(V601) and 1,1′-azobis(cyclohexane-1-carbonitrile)(V40) initiators were purchased from Wako Specialty Chemicals. Diphenyliodonium-2-carboxylate monohydrate (DPIC), diphenyl(p-phenyl) sulfonium 2-(((3r,5r,7r)-adamantane-1-carbonyl)oxy)-1,1-difluoroethane-1-sulfonate (TDPS IAD), 4-(4-(tert-butyl)phenyl)-1,4-oxathian-4-ium tris((trifluoromethyl) sulfonyl) methanide (TBPTO Cl), ethylcyclopentyl methacrylate (ECPMA), y-butyrolacton-2-yl methacrylate («-GBLMA), 2-oxohexahydro-2H-3,5-methanocyclopenta [b]furan-6-yl methacrylate (NLMA), propylene glycol monomethyl ether acetate (PGMEA), anisole, ethoxymethyl methacrylate (EOMMA), 5-methyl-3-methylenedihydrofuran-2 (3H)-one (aMMBL), 2-(adamantan-1-yl) propan-2-yl methacrylate (IAM), 3-hydroxyadamantan-1-yl methacrylate (HAMA), (cyclohexyloxy)methyl methacrylate (CHOMMA), and 2-cyano-2-propyl dodecyl trithiocarbonate were purchased from commercial sources and used without further purification.

### ECPMA/α-GBLMA/NLMA Copolymer Synthesis

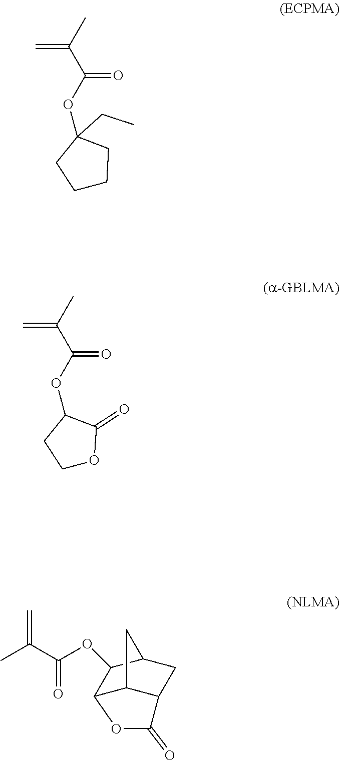 [SMILES: C=C(C)C(=O)OC1(CC)CCCC1 ; C=C(C)C(=O)OC1CCOC1=O ; C=C(C)C(=O)OC1C2CC3C(=O)OC1C3C2]

### Triblock Copolymer Synthesis. (ECPMA/α-GBLMA/NLMA)

The triblock Copolymers 1 to 4 were prepared as follows. A mixture of 26.1 grams (g) of ECPMA, 23.0 g of a-GBLMA, and 15.3 g of NLMA were mixed with 40.0 g of anisole to provide a monomer solution having a solids content of 62 wt %. In a separate vial, 22.3 g of the as-prepared monomer solution was charge with 92 milligrams (mg) of V40 initiator. The solution was degassed with nitrogen and taken into a syringe as the feed mixture. In the reactor, 318 mg of 2-cyano-2-propyl dodecyl trithiocarbonate was used as the chain transfer agent (CTA) and protected under N₂ at 110° C. One third of the feed mixture was added to the reactor, and the resulting reaction mixture was heated for 120 minutes. Then, another third of the feed mixture was added to the reactor, and the reaction mixture was heated for another 120 minutes. The final third of the fee mixture was then added to the reactor and the reaction mixture was heated for 120 minutes. Aliquots were taken from the reaction mixture under gentle N2 flow when needed for analysis. The triblock copolymer was isolated by precipitation into isopropanol. The conversions reached>90% at the end of each block of the polymerization.

### Multiblock Copolymer Synthesis. (ECPMA/α-GBLMA/NLMA)

The multiblock Copolymer 5 was prepared as follows. A mixture of 8.83 g of ECPMA, 7.51 g of α-GBLMA, and 5.01 g of NLMA was mixed with 14.21 g of anisole to provide a monomer solution having a solids content of 60 wt %. In a separate vial, 12.99 g of the as-prepared monomer solution was charged with 162 mg of V40 initiator. The solution was degassed with nitrogen and taken into a syringe as the feed mixture. In a reactor, 225 mg of 2-cyano-2-propyl dodecyl trithiocarbonate was used as CTA and protected under N₂ at 110° C. One seventh of the feed mixture was added to the reactor every hour, and aliquots were taken from the reaction mixture under gentle N2 flow when needed. The polymer was isolated by precipitation into isopropanol. The conversions reached>90% at the end of each block of the polymerization.

### End Group Removal

The end groups were removed from Copolymers 2, 4, and 5 by using the following procedure. The respective block copolymer was dissolved PGMEA (to provide a solids content of 15 wt %) with gentle heating. After cooling to lower than 40° C., 20 equivalents of V601 initiator (relative to the trithiocarbonate groups of the block copolymer) were added to the solution. The solution was heated to 80° C. for 3 hours and precipitated into isopropanol to obtain the block copolymer without the trithiocarbonate end groups.

### Comparative Copolymers. (ECPMA/α-GBLMA/NLMA)

The random Copolymer 6 (comparative) was prepared as follows. A reactor was charged with 112 g of a degassed mixture of ethyl lactate (70 wt %) and 1,4-lactone (30 wt %), and heated to 80° C. A degassed monomer feed solution was prepared from a combination of 318.3 g of solvent (ethyl lactate/1,4-lactone, 7:3 w/w), 95.9 g of ECPMA, 88.9 g of α-GBLMA, and 58 g of NLMA. Separately, a degassed initiator feed solution was prepared using 12.4 g of V601 initiator and 125.2 g of solvent (ethyl lactate/1,4-lactone, 7:3 w/w). The monomer feed solution and the initiator feed solution were then continuously added to the reactor at the same time, with the monomer feed solution being added over the course of 240 minutes and the initiator feed solution being added over the course of 210 minutes. The reactor was then cooled at a rate of 1° C./min to ambient temperature. The copolymer was isolated by precipitation into methanol and the product was dried before use.

The random Copolymer 7 (comparative) was prepared as follows. A reactor was charged with 11.2 g of a degassed PGMEA and heated to 80° C. A degassed monomer feed solution was prepared from a combination of 10.245 g of ECPMA, 9.556 g of α-GBLMA, and 6.244 g of NLMA. Separately, a degassed initiator feed solution was prepared using 1.541 g of V601 initiator and 13.902 g of PGMEA. The monomer feed solution and the initiator feed solution were then continuously added to the reactor at the same time, with the monomer feed solution being added over the course of 240 minutes and the initiator feed solution being added over the course of 210 minutes. Five hours after initiation of the feed solutions, the reactor was then cooled at a rate of 1° C./min to ambient temperature. The copolymer was isolated by precipitation into methanol and the product was dried before use.

The block copolymers and comparative copolymers derived from the monomer combination ECPMA/α-GBLMA/NLMA (40/40/20 mole ratio) are summarized in Table 1.

TABLE 1

| | | End-group | Mₙ | M_{w} | |
|---|---|---|---|---|---|
| Copolymer | Structure | removal | (g/mol) | (g/mol) | Ð |
| 1 | Triblock | No | 7106 | 9595 | 1.35 |
| 2 | Triblock | Yes | 7446 | 9830 | 1.32 |
| 3 | Triblock | No | 7428 | 10976 | 1.35 |
| 4 | Triblock | Yes | 7504 | 11196 | 1.37 |
| 5 | Multiblock | Yes | 7054 | 9788 | 1.39 |
| | (7) | | | | |
| 6 (comp) | Random | N/A | 5028 | 8806 | 1.75 |
| 7 (comp) | Random | N/A | 8366 | 14911 | 1.78 |

M_{w}. Mₙ, and dispersity index (D) were determined by GPC using polystyrene standards.

### Synthesis of Additive E1

A monomer solution was prepared by combining 192.00 g of GMEA, 133.2 g of (methacryloyloxy)methylene bis(2,2-difluoro-3,3-dimethylbutanoate), and 8.51 g of ethylcyclopentyl methacrylate in a flask and agitating the resulting mixture to dissolve the components. Separately, an initiator solution was prepared by combining 10.72 g of PGMEA and 6.2 g of V601 initiator in a flask. 20.05 g of PGMEA was introduced into a separate reaction vessel and the vessel was purged with nitrogen for 30 minutes. The reaction vessel was next heated to 95° C. with agitation. The monomer solution and initiator solutions were then introduced as separate feeds into the reaction vessel over a period of 2.5 hours. Upon completion of the 2.5 hours, the reaction vessel was maintained at 95° C. for an additional 3 hours with agitation, and was then allowed to cool to room temperature. Additive El was obtained with a M_{w}/Mₙ (kg/mol) of 9.658/6.192 as determined by GPC using polystyrene standards.

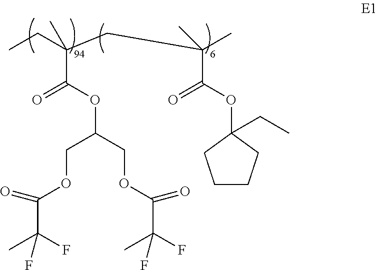

### Photoresist Preparation.

Positive tone photoresist compositions PR1 to PR11 were prepared by dissolving solid components (copolymer, PAG, quencher, and additive) in solvents using the materials and amounts indicated in Table 2, where the amounts are expressed in wt % based on 100 wt % of total weight of the solids. The total solids content for the photoresist compositions was 3.1%. The solvent system contained PGMEA (S1) and 2-hydroxyisobutyric acid methyl ester (S2). Each mixture was shaken in a 100 mL glass container on a mechanical shaker and filtered through a PTFE disk-shaped filter having a pore size of 0.20 micrometers.

TABLE 2

| Photoresist | | | | | |
|---|---|---|---|---|---|
| Composition | Copolymer | PAG | Quencher | Additive | Solvent |
| PR1 | 1 | TBPTO C1 | DPIC | E1 | S1 / S2 |
| | [83.41] | [10.49] | [3.1] | [3] | [35:65 w/w] |
| PR2 | 2 | TBPTO C1 | DPIC | E1 | S1 / S2 |
| | [83.41] | [10.49] | [3.1] | [3] | [35:65 w/w] |
| PR3 | 3 | TBPTO C1 | DPIC | E1 | S1 / S2 |
| | [83.41] | [10.49] | [3.1] | [3] | [35:65 w/w] |
| PR4 | 4 | TBPTO C1 | DPIC | E1 | S1 / S2 |
| | [83.41] | [10.49] | [3.1] | [3] | [35:65 w/w] |
| PR5 | 5 | TBPTO C1 | DPIC | E1 | S1 / S2 |
| | [83.41] | [10.49] | [3.1] | [3] | [35:65 w/w] |
| PR6 (comp) | 6 (comp) | TBPTO C1 | DPIC | E1 | S1 / S2 |
| | [83.41] | [10.49] | [3.1] | [3] | [35:65 w/w] |
| PR7 (comp) | 7 (comp) | TBPTO C1 | DPIC | E1 | S1 / S2 |
| | [83.41] | [10.49] | [3.1] | [3] | [35:65 w/w] |
| PR8 (comp) | 6 (comp) | TDPS IAD | DPIC | E1 | S1 / S2 |
| | [79.60] | [15.05] | [2.32] | [3] | [35:65 w/w] |
| PR9 | 1 | TDPS IAD | DPIC | E1 | S1 / S2 |
| | [79.60] | [15.05] | [2.32] | [3] | [35:65 w/w] |
| PR10 | 2 | TDPS IAD | DPIC | E1 | S1 / S2 |
| | [79.60] | [15.05] | [2.32] | [3] | [35:65 w/w] |
| PR11 | 5 | TDPS IAD | DPIC | E1 | S1 / S2 |
| | [79.60] | [15.05] | [2.32] | [3] | [35:65 w/w] |

### Lithographic Testing—Examples 1 to 14

### E_{size}, EL %, and LWR Evaluation

300 mm silicon wafers were spin-coated with AR™ 40A antireflectant (DuPont Electronics & Industrial) using a cure temperature of 205° C. for 60 seconds to form a first BARC layer having a thickness of 80 nm. The wafers were then spin-coated with AR™ 104 antireflectant (DuPont Electronics & Industrial) using a cure temperature of 175° C. for 60 seconds to form a second BARC layer having a thickness of 40 nm. The wafers were then spin-coated with a respective photoresist composition from Table 2 and soft-baked at 90° C. for 60 seconds to provide a photoresist layer having a thickness of 90 nm. The BARC and photoresist layers were coated with a TEL CLEAN TRACK™ LITHIUS™ coating tool. The wafers were exposed to 193 nm activating radiation using an Nikon S610C immersion scanner (1.30 NA, 0.98/0.79 inner/outer sigma, dipole illumination with 35Y polarization) using a mask having line-space patterns (38 nm linewidth/80 nm pitch or 38 nm linewidth/86 nm pitch) at various doses. The exposed wafers were post-exposure baked at 95° C. for 60 seconds and developed with a 0.26 N aqueous tetramethylammonium hydroxide (TMAH) solution (MF™-CD26, DuPont Electronics & Industrial) for 12 seconds. The wafers were then rinsed with DI water and spin-dried to form photoresist patterns. CD linewidth measurements of the formed patterns were made using a Hitachi High Technologies Co. CG4000 CD-SEM.

Line-space patterns in nanometers (nm) were analyzed for critical dimension (CD), where sizing energy “E_{size}” is the irradiation energy when the CD of the formed line-space pattern is equal to the CD of the mask pattern. E_{size} is expressed in units of millijoules per square centimeter (mJ/cm²). Exposure latitude (EL %) is the difference in exposure energy required to print the line-space patterns at plus and minus 10% of the target diameter, normalized by the sizing energy. Linewidth roughness (LWR) is expressed in units of nanometers (nm) and was determined as the 3-sigma value from the distribution of a total of 100 arbitrary points of line width measurements, followed by removing metrology noise. The E_{size}, EL %, and LWR data are shown in Tables 3a and 3b.

### E₀ Evaluation

200 mm silicon wafers were spin-coated with AR™40A antireflectant (DuPont Electronics & Industrial) using a cure temperature of 205° C. for 60 seconds to form a BARC layer having a thickness of 80 nm. The wafers were then spin-coated with a respective photoresist composition from Table 2 and soft-baked at 90° C. for 60 seconds to provide a photoresist layer having a thickness of 90 nm. The BARC and photoresist layers were coated with a TEL CLEAN TRACK™ ACT™ 8 coating tool. The wafers were exposed to 193 nm activating radiation using an ASML 1100 scanner (0.75 NA, 0.89/0.64 inner/outer sigma with Quadrapole-30) at various doses. The exposed wafers were post-exposure baked at 95° C. for 60 seconds and developed with a 0.26 N aqueous TMAH solution (MF™-CD26, DuPont Electronics & Industrial) for 60 seconds. The wafers were then rinsed with DI water and spin-dried. Film thickness was measured with a KLA Therma-Wave Opti-Probe 7341 at each exposed area and plotted vs. dose. E₀ values (mJ/cm²) were determined as the first dose value at which the remaining film thickness was less than 7% of the original coated thickness. The E₀ data is shown in Tables 3a and 3b.

TABLE 3a

| | | | 38 nm/80 p | | | |
|---|---|---|---|---|---|---|
| | | | | | | LWR * |
| | Photoresist | | | | | sqrt |
| Example | Composition | E₀ | E_{size} | EL % | LWR | (E_{size}) |
| 1 | PR1 | 10.6 | 52.6 | 23.88 | 2.37 | 17.2 |
| 2 | PR2 | 10.4 | 47.2 | 25.81 | 2.51 | 17.2 |
| 3 | PR3 | 10.6 | 51.7 | 24.46 | 2.32 | 16.7 |
| 4 | PR4 | 10.2 | 48.1 | 25.75 | 2.34 | 16.2 |
| 5 | PR5 | 10.2 | 51.4 | 21.97 | 2.26 | 16.2 |
| 6 (comp) | PR6 | 9.6 | 46.5 | 24.30 | 2.45 | 16.7 |
| 7 (comp) | PR7 | 9.4 | 49.8 | 20.72 | 2.20 | 15.5 |

TABLE 3b

| | | | 38 nm/86 p | | | |
|---|---|---|---|---|---|---|
| | | | | | | LWR * |
| | Photoresist | | | | | sqrt |
| Example | Composition | E₀ | E_{size} | EL % | LWR | (E_{size}) |
| 8 | PR1 | 10.6 | 40.0 | 27.83 | 2.05 | 13.0 |
| 9 | PR2 | 10.4 | 38.0 | 24.02 | 2.22 | 13.7 |
| 10 | PR3 | 10.6 | 42.0 | 26.58 | 2.09 | 13.5 |
| 11 | PR4 | 10.2 | 39.0 | 24.40 | 2.12 | 13.2 |
| 12 | PR5 | 10.2 | 40.6 | 26.96 | 2.08 | 13.3 |
| 13 (comp) | PR6 | 9.6 | 37.4 | 25.82 | 2.03 | 12.4 |
| 14 (comp) | PR7 | 9.4 | 39.9 | 27.39 | 2.05 | 12.9 |

### Lithographic Testing—Examples 15 to 30

### E_{size}, EL %, LWR, and PCM Evaluation

300 mm silicon wafers were spin-coated with AR™ 40A antireflectant (DuPont Electronics & Industrial) using a cure temperature of 205° C. for 60 seconds to form a first BARC layer having a thickness of 80 nm. The wafers were then spin-coated with AR™ 104 antireflectant (DuPont Electronics & Industrial) using a cure temperature of 175° C. for 60 seconds to form a second BARC layer having a thickness of 40 nm. The wafers were then spin-coated with a respective photoresist composition from Table 2 and soft-baked at 90° C. for 60 seconds to provide a photoresist layer having a thickness of 90 nm. The BARC and photoresist layers were coated with a TEL CLEAN TRACK™ LITHIUS™ coating tool. The wafers were exposed to 193 nm activating radiation using ASML 1900i immersion scanner (1.35 NA, 0.988/0.90 inner/outer sigma, dipole illumination with 35Y polarization) using a mask having 1:1 line-space patterns (38 nm linewidth/76 nm pitch or 37 nm linewidth/74 nm pitch) at various doses. The exposed wafers were post-exposure baked at 95° C. for 60 seconds and developed with a 0.26 N aqueous tetramethylammonium hydroxide (TMAH) solution (MF™-CD26, DuPont Electronics & Industrial) for 12 seconds. The wafers were then rinsed with DI water and spin-dried to form photoresist patterns. CD linewidth measurements of the formed patterns were made using a Hitachi High Technologies Co. CG4000 CD-SEM.

Line-space patterns in nanometers (nm) were analyzed for critical dimension (CD), where sizing energy “E_{size}” is the irradiation energy when the CD of the formed line-space pattern is equal to the CD of the mask pattern. E_{size} is expressed in units of millijoules per square centimeter (mJ/cm²). Exposure latitude (EL %) is the difference in exposure energy required to print the line-space patterns at plus and minus 10% of the target diameter, normalized by the sizing energy. Linewidth roughness (LWR) is expressed in units of nanometers (nm) and was determined as the 3-sigma value from the distribution of a total of 100 arbitrary points of line width measurements, followed by removing metrology noise. PCM is pattern collapse margin, which is expressed in units of nanometers. The E_{size}, EL %, LWR, and PCM data are shown in Tables 4a and 4b.

### E₀ Evaluation

200 mm silicon wafers were spin-coated with AR™40A antireflectant (DuPont Electronics & Industrial) using a cure temperature of 205° C. for 60 seconds to form a BARC layer having a thickness of 80 nm. The wafers were then spin-coated with a respective photoresist composition from Table 2 and soft-baked at 90° C. for 60 seconds to provide a photoresist layer having a thickness of 90 nm. The BARC and photoresist layers were coated with a TEL CLEAN TRACK™ ACT™ 8 coating tool. The wafers were exposed to 193 nm activating radiation using an ASML 1100 scanner (0.75 NA, 0.89/0.64 inner/outer sigma with Quadrapole-30) at various doses. The exposed wafers were post-exposure baked at 95° C. for 60 seconds and developed with a 0.26 N aqueous TMAH solution (MF™-CD26, DuPont Electronics & Industrial) for 60 seconds. The wafers were then rinsed with DI water and spin-dried. Film thickness was measured with a KLA Therma-Wave Opti-Probe 7341 at each exposed area and plotted vs. dose. E₀ values (mJ/cm²) were determined as the first dose value at which the remaining film thickness was less than 7% of the original coated thickness. The E₀ data is shown in Tables 4a and 4b.

TABLE 4a

| | Photo- | | 38 nm/76 p | | | | |
|---|---|---|---|---|---|---|---|
| | resist | | | | | | LWR |
| | Com- | | | | | | * sqrt |
| Example | position | E₀ | E_{size} | EL % | LWR | PCM | (E_{size}) |
| 15 (comp) | PR6 | 9.4 | 31.7 | 28.7 | 2.11 | 22.3 | 11.9 |
| 16 | PR1 | 10.8 | 33.9 | 30.1 | 2.11 | 24.1 | 12.3 |
| 17 | PR2 | 10.6 | 30.0 | 31.4 | 2.26 | 27.8 | 12.4 |
| 18 | PR5 | 10.2 | 33.2 | 29.2 | 2.28 | 24.2 | 13.1 |
| 19 (comp) | PR8 | 4.2 | 13.7 | 21.1 | 2.82 | 30.9 | 10.4 |
| 20 | PR9 | 4.2 | 12.6 | 22.5 | 2.64 | 25.1 | 9.4 |
| 21 | PR10 | 4.0 | 11.1 | 22.0 | 2.91 | 26.4 | 9.7 |
| 22 | PR11 | 4.4 | 13.5 | 20.3 | 2.75 | 27.3 | 10.1 |

TABLE 4b

| | Photo- | | 37 nm/74 p | | | | |
|---|---|---|---|---|---|---|---|
| | resist | | | | | | LWR |
| | Com- | | | | | | * sqrt |
| Example | position | E₀ | E_{size} | EL % | LWR | PCM | (E_{size}) |
| 23 (comp) | PR6 | 9.4 | 45.7 | 16.1 | 3.73 | 25.1 | 25.2 |
| 24 | PR1 | 10.8 | 45.2 | 16.5 | 3.63 | 25.8 | 24.4 |
| 25 | PR2 | 10.6 | 42.3 | 15.8 | 3.72 | 26.9 | 24.2 |
| 26 | PR5 | 10.2 | 44.6 | 16.1 | 3.49 | 24.3 | 23.3 |
| 27 (comp) | PR8 | 4.2 | 19.7 | 14.0 | 5.28 | 35.8 | 23.4 |
| 28 | PR9 | 4.2 | 18.3 | 16.1 | 4.51 | 30.5 | 19.3 |
| 29 | PR10 | 4.0 | 16.4 | 16.7 | 5.06 | 25.5 | 20.5 |
| 30 | PR11 | 4.4 | 19.8 | 15.0 | 4.77 | 31.8 | 21.2 |

### EOMMA/ECPMA/α-GBLMA/aMMBL Copolymer Synthesis

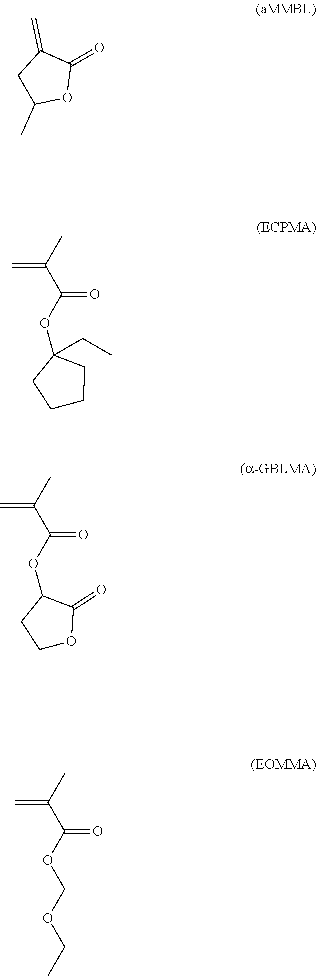

### Triblock Copolymer Synthesis. (EOMMA/ECPMA/α-GBLMA/aMMBL)

The triblock Copolymer 9 was prepared as follows. A monomer mixture of 11.5 g of α-GBLMA, 12.7 g of ECPMA, 7.6 g of aMMBL, and 3.2 g of EOMMA was prepared. 11.0 g of the monomer mixture was combined with 5.5 g of PGMEA and 148 mg of V40 initiator to provide a feed solution. The feed solution was degassed and taken into a syringe before use. In the reactor, 468 mg of 2-cyano-2-propyl dodecyl trithiocarbonate was used as the chain transfer agent (CTA) and protected under N₂ at 115° C. One third of the feed solution was added to the CTA and heated for 90 minutes; another one third of the feed solution was added to the CTA and heated for 90 minutes; and then the remainder of the feed solution was added to the CTA and heated for 120 minutes. Aliquots were taken from the reaction mixture under a gentle N2 flow when needed. The block copolymer was isolated by precipitation into isopropanol. It was found that the conversions reached>90% at the end of each block of polymerization.

### Multiblock Copolymer Synthesis. (EOMMA/ECPMA/α-GBLMA/aMMBL)

The multiblock Copolymer 10 was prepared as follows. A monomer mixture of 11.5 g of α-GBLMA, 12.7 g of ECPMA, 7.6 g of aMMBL, and 3.2 g of EOMMA was prepared. 11.0 g of the monomer mixture was combined with 5.7 g of PGMEA and 285 mg of V40 initiator to provide a feed solution. The feed solution was degassed and taken into a syringe before use. In the reactor, 397 mg of 2-cyano-2-propyl dodecyl trithiocarbonate was used as the CTA and protected under N₂ at 115° C. About 1/9 of the feed solution was added to the CTA and heated for 60 minutes; this addition was repeated 8 more times with heating between each subsequent addition of the feed solution. Aliquots were taken from the reaction mixture under gentle N₂ flow when needed. The block copolymer was isolated by precipitation into isopropanol. It was found that the conversions reached>90% at the end of each block of polymerization.

### Tetrablock Copolymer Synthesis. (EOMMA/ECPMA/α-GBLMA/aMMBL)

The tetrablock Copolymer 11 was prepared by an analogous method as used to prepare Copolymers 9 and 10.

### Comparative Copolymers. (EOMMA/ECPMA/α-GBLMA/aMMBL)

The random Copolymer 8 (comparative) was prepared as follows. 6.3 g of a monomer mixture (EOMMA/ECPMA/α-GBLMA/aMMBL in a molar ratio of Oct. 30, 1930/30) was combined with 8.2 g of PGMEA and 711 mg of V601 initiator, and the mixture was degassed. After being heated at 85° C. for 160 minutes, the copolymer was precipitated into isopropanol.

The block copolymers and comparative copolymers derived from the monomer combination EOMMA/ECPMA/α-GBLMA/aMMBL (Oct. 30, 1930/30 mole ratio) are summarized in Table 5.

TABLE 5

| | | End-group | Mₙ | M_{w} | |
|---|---|---|---|---|---|
| Copolymer | Structure | removal | (g/mol) | (g/mol) | Ð |
| 8 (comp) | Random | No | 5355 | 13013 | 2.34 |
| 9 | Triblock | No | 7452 | 9317 | 1.25 |
| 10 | Multiblock | No | 6725 | 9898 | 1.47 |
| | (7) | | | | |
| 11 | Tetrablock | No | 7047 | 9150 | 1.30 |

M_{w}. Mₙ, and dispersity index (D) were determined by GPC using polystyrene standards.

### Photoresist Preparation

Positive tone photoresist compositions PR12 to PR19 were prepared by dissolving solid components (copolymer, PAG, quencher, and additive) in solvents using the materials and amounts indicated in Table 6, where the amounts are expressed in wt % based on 100 wt % of total weight of the solids. The total solids content for the photoresist compositions was 3.1%. The solvent system contained propylene glycol methyl ether acetate (S1) and 2-hydroxyisobutyric acid methyl ester (S2). Each mixture was shaken in a 100 mL glass container on a mechanical shaker and filtered through a PTFE disk-shaped filter having a pore size of 0.20 micrometers.

TABLE 6

| Photoresist | | | | | |
|---|---|---|---|---|---|
| Composition | Copolymer | PAG | Quencher | Additive | Solvent |
| PR12 (comp) | 8 (comp) | TBPTO C1 | DPIC | E1 | S1 / S2 |
| | [83.41] | [10.49] | [3.1] | [3] | [35:65 w/w] |
| PR13 | 9 | TBPTO C1 | DPIC | E1 | S1 / S2 |
| | [83.41] | [10.49] | [3.1] | [3] | [35:65 w/w] |
| PR14 | 10 | TBPTO C1 | DPIC | E1 | S1 / S2 |
| | [83.41] | [10.49] | [3.1] | [3] | [35:65 w/w] |
| PR15 | 11 | TBPTO C1 | DPIC | E1 | S1 / S2 |
| | [83.41] | [10.49] | [3.1] | [3] | [35:65 w/w] |
| PR16 (comp) | 8 (comp) | TDPS IAD | DPIC | E1 | S1 / S2 |
| | [79.60] | [15.05] | [2.32] | [3] | [35:65 w/w] |
| PR17 | 9 | TDPS IAD | DPIC | E1 | S1 / S2 |
| | [79.60] | [15.05] | [2.32] | [3] | [35:65 w/w] |
| PR18 | 10 | TDPS IAD | DPIC | E1 | S1 / S2 |
| | [79.60] | [15.05] | [2.32] | [3] | [35:65 w/w] |
| PR19 | 11 | TDPS IAD | DPIC | E1 | S1 / S2 |
| | [79.60] | [15.05] | [2.32] | [3] | [35:65 w/w] |

### Lithographic Testing—Examples 31 to 54

### E_{size}, EL %, LWR, and PCM Evaluation

300 mm silicon wafers were spin-coated with AR™ 40A antireflectant (DuPont Electronics & Industrial) using a cure temperature of 205° C. for 60 seconds to form a first BARC layer having a thickness of 80 nm. The wafers were then spin-coated with AR™ 104 antireflectant (DuPont Electronics & Industrial) using a cure temperature of 175° C. for 60 seconds to form a second BARC layer having a thickness of 40 nm. The wafers were then spin-coated with a respective photoresist composition from Table 6 and soft-baked at 90° C. for 60 seconds to provide a photoresist layer having a thickness of 90 nm. The BARC and photoresist layers were coated with a TEL CLEAN TRACK™ LITHIUS™ coating tool. The wafers were exposed to 193 nm activating radiation using ASML 1900i immersion scanner (1.35 NA, 0.988/0.90 inner/outer sigma, dipole illumination with 35Y polarization) using a mask having line-space patterns (38 nm linewidth/76 nm pitch, 37 nm linewidth/74 nm pitch, 34 nm linewidth/74 nm pitch, or 32 nm linewidth/74 nm pitch) at various doses. The exposed wafers were post-exposure baked at 95° C. for 60 seconds and developed with a 0.26 N aqueous TMAH solution (MF™-CD26, DuPont Electronics & Industrial) for 12 seconds. The wafers were then rinsed with DI water and spin-dried to form photoresist patterns. CD linewidth measurements of the formed patterns were made using a Hitachi High Technologies Co. CG4000 CD-SEM.

Line-space patterns in nanometers (nm) were analyzed for critical dimension (CD), where sizing energy “E_{size}” is the irradiation energy when the CD of the formed line-space pattern is equal to the CD of the mask pattern. E_{size} is expressed in units of millijoules per square centimeter (mJ/cm²). Exposure latitude (EL %) is the difference in exposure energy required to print the line-space patterns at plus and minus 10% of the target diameter, normalized by the sizing energy. Linewidth roughness (LWR) is expressed in units of nanometers (nm) and was determined as the 3-sigma value from the distribution of a total of 100 arbitrary points of line width measurements, followed by removing metrology noise. PCM is pattern collapse margin, which is expressed in units of nanometers. The E_{size}, EL %, LWR, and PCM data are shown in Tables 7a, 7b, and 7c.

TABLE 7a

| | Photo- | 38 nm/76 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 31 (comp) | PR12 | 38.1 | 29.9 | 2.15 | 27.8 | 13.3 |
| 32 | PR13 | 42.3 | 29.6 | 2.18 | 25.5 | 14.2 |
| 33 | PR14 | 36.5 | 29.6 | 2.26 | 29.5 | 13.6 |
| 34 | PR15 | 42.0 | 29.5 | 2.12 | 24.8 | 13.8 |
| 35 (comp) | PR16 | 13.5 | 22.7 | 2.60 | 28.6 | 9.6 |
| 36 | PR17 | 13.1 | 22.8 | 2.58 | 27.3 | 9.3 |
| 37 | PR18 | 11.1 | 21.0 | 2.88 | 26.1 | 9.6 |
| 38 | PR19 | 13.6 | 23.8 | 2.51 | 28.5 | 9.2 |

TABLE 7b

| | Photo- | 37 nm/74 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 39 (comp) | PR12 | 47.4 | 17.8 | 3.76 | 30.8 | 25.9 |
| 40 | PR13 | 53.2 | 17.5 | 3.76 | 27.7 | 27.4 |
| 41 | PR14 | 47.5 | 17.4 | 3.77 | 30.0 | 26.0 |
| 42 | PR15 | 51.8 | 16.8 | 3.84 | 30.5 | 27.6 |
| 43 (comp) | PR16 | 18.4 | 16.4 | 4.68 | 32.2 | 20.1 |
| 44 | PR17 | 18.4 | 16.4 | 4.35 | 31.7 | 18.6 |
| 45 | PR18 | 17.1 | 18.9 | 4.64 | 26.1 | 19.2 |
| 46 | PR19 | 18.9 | 17.0 | 4.74 | 33.1 | 20.6 |

TABLE 7c

| | | |
|---|---|---|
| Photoresist | 34 nm/74 p | 32 nm/74 p |

| Example | Composition | E_{size} | LWR | E_{size} | LWR |
|---|---|---|---|---|---|
| 47 (comp) | PR12 | 43.7 | 3.49 | 38.3 | 4.37 |
| 48 | PR13 | 48.4 | 3.37 | 44.2 | 4.06 |
| 49 | PR14 | 44.1 | 3.71 | 39.6 | 4.81 |
| 50 | PR15 | 46.7 | 3.50 | 42.3 | 4.17 |
| 51 (comp) | PR16 | 16.8 | 4.49 | 15.4 | 5.61 |
| 52 | PR17 | 16.7 | 4.43 | 14.9 | 5.63 |
| 53 | PR18 | 15.1 | 4.12 | 13.9 | 4.37 |
| 54 | PR19 | 17.5 | 4.54 | 15.7 | 6.22 |

### IAM/α-GBLMA/HAMA Copolymer Synthesis

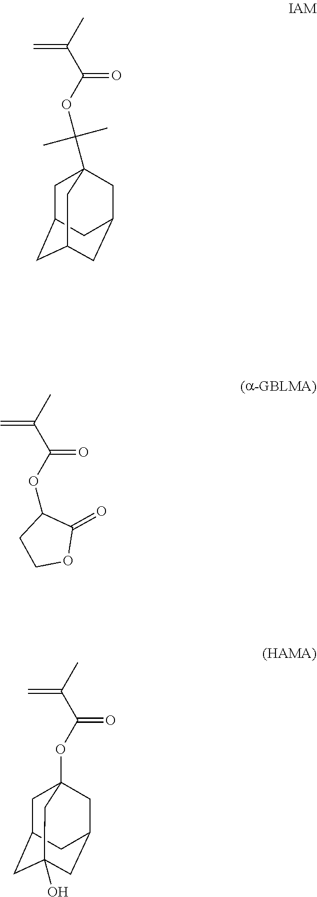 [SMILES: C=C(C)C(=O)OC(C)(C)C12CC3CC(CC(C3)C1)C2 ; C=C(C)C(=O)OC1CCOC1=O ; C=C(C)C(=O)OC12CC3CC(CC(O)(C3)C1)C2]

### Multiblock Copolymer Synthesis. (IAM/α-GBLMA/HAMA)

The multiblock Copolymer 12 was prepared as follows. A monomer solution of 18.3 g of IAM, 11.0 g of HAMA, 19.3 g of α-GBLMA, and 24.5 g of PGMEA was prepared. 12.3 g of the monomer solution was combined with 227 mg of V40 initiator as the feed solution. The feed solution was degassed and taken into a syringe before use. In the reactor, 353 mg of 2-cyano-2-propyl dodecyl trithiocarbonate was used as the CTA and protected under N₂ at 110° C. About ⅛ of the feed solution was added to the CTA and heated for 60 minutes; this addition was repeated 7 more times with heating following each subsequent addition. Aliquots were taken from the reaction mixture under gentle N₂ flow when needed. The block copolymer was isolated by precipitation into isopropanol. It was found that the conversions reached>97% at the end of each block of polymerization.

### Comparative Copolymer. (IAM/α-GBLMA/HAMA)

The comparative Copolymer 13 was prepared as follows. A monomer solution of 18.3 g of IAM, 11.0 g of HAMA, 19.3 g of α-GBLMA, and 24.5 g of PGMEA was prepared. In a reactor, 153 mg of 2-cyano-2-propyl dodecyl trithiocarbonate was used as the CTA and combined with 7.7 g of the monomer solution, 15.3 g of PGMEA, and 1520 mg of V40 initiator. After degassing, the mixture was heated to 95° C. for 26 hours, cooled to room temperature, and then precipitated into isopropanol.

The block copolymer and comparative copolymer derived from the monomer combination IAM/α-GBLMA/HAMA (30/50/20 mole ratio) are summarized in Table 8.

TABLE 8

| | | End-group | Mₙ | M_{w} | |
|---|---|---|---|---|---|
| Copolymer | Structure | removal | (g/mol) | (g/mol) | Ð |
| 12 | Multiblock | No | 4406 | 5894 | 1.34 |
| | (8) | | | | |
| 13 | RAFT | No | 4844 | 7618 | 1.57 |
| | Dump-Run | | | | |

M_{w}. Mₙ, and dispersity index (D) were determined by GPC using polystyrene standards.

### Photoresist Preparation.

Positive tone photoresist compositions PR20 to PR23 were prepared by dissolving solid components (copolymer, PAG, quencher, and additive) in solvents using the materials and amounts indicated in Table 9, where the amounts are expressed in wt % based on 100 wt % of total weight of the solids. The total solids content for the photoresist compositions was 2.9%. The solvent system contained PGMEA (S1) and 2-hydroxyisobutyric acid methyl ester (S2). Each mixture was shaken in a 100 mL glass container on a mechanical shaker and filtered through a PTFE disk-shaped filter having a pore size of 0.20 micrometers.

TABLE 8

| Photoresist | | | | | |
|---|---|---|---|---|---|
| Composition | Copolymer | PAG | Quencher | Additive | Solvent |
| PR20 | 12 | TBPTO C1 | DPIC | E1 | S1 / S2 |
| | [83.41] | [10.49] | [3.1] | [3] | [35:65 w/w] |
| PR21 (comp) | 13 (comp) | TBPTO C1 | DPIC | E1 | S1 / S2 |
| | [83.41] | [10.49] | [3.1] | [3] | [35:65 w/w] |
| PR22 | 12 | TDPS IAD | DPIC | E1 | S1 / S2 |
| | [79.60] | [15.05] | [2.32] | [3] | [35:65 w/w] |
| PR23 (comp) | 13 (comp) | TDPS IAD | DPIC | E1 | S1 / S2 |
| | [79.60] | [15.05] | [2.32] | [3] | [35:65 w/w] |

### Lithographic Testing—Examples 55 to 66

### E_{size}, EL %, LWR, and PCM Evaluation

300 mm silicon wafers were spin-coated with AR™ 40A antireflectant (DuPont Electronics & Industrial) using a cure temperature of 205° C. for 60 seconds to form a first BARC layer having a thickness of 80 nm. The wafers were then spin-coated with AR™ 104 antireflectant (DuPont Electronics & Industrial) using a cure temperature of 175° C. for 60 seconds to form a second BARC layer having a thickness of 40 nm. The wafers were then spin-coated with a respective photoresist composition from Table 6 and soft-baked at 90° C. for 60 seconds to provide a photoresist layer having a thickness of 90 nm. The BARC and photoresist layers were coated with a TEL CLEAN TRACK™ LITHIUS™ coating tool. The wafers were exposed to 193 nm activating radiation using ASML 1900i immersion scanner (1.35 NA, 0.988/0.90 inner/outer sigma, dipole illumination with 35Y polarization) using a mask having line-space patterns (38 nm linewidth/76 nm pitch, 37 nm linewidth/74 nm pitch, 34 nm linewidth/74 nm pitch, or 32 nm linewidth/74 nm pitch) at various doses. The exposed wafers were post-exposure baked at 95° C. for 60 seconds and developed with a 0.26 N aqueous TMAH solution (MF™-CD26, DuPont Electronics & Industrial) for 12 seconds. The wafers were then rinsed with DI water and spin-dried to form photoresist patterns. CD linewidth measurements of the formed patterns were made using a Hitachi High Technologies Co. CG4000 CD-SEM.

Line-space patterns in nanometers (nm) were analyzed for critical dimension (CD), where sizing energy “E_{size}” is the irradiation energy when the CD of the formed line-space pattern is equal to the CD of the mask pattern. E_{size} is expressed in units of millijoules per square centimeter (mJ/cm²). Exposure latitude (EL %) is the difference in exposure energy required to print the line-space patterns at plus and minus 10% of the target diameter, normalized by the sizing energy. Linewidth roughness (LWR) is expressed in units of nanometers (nm) and was determined as the 3-sigma value from the distribution of a total of 100 arbitrary points of line width measurements, followed by removing metrology noise. PCM is pattern collapse margin, which is expressed in units of nanometers. The E_{size}, EL %, LWR, and PCM data are shown in Tables 9a, 9b, and 9c.

TABLE 9a

| | Photo- | 38 nm/76 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 55 | PR20 | 59.0 | 21.8 | 2.54 | 34.7 | 19.5 |
| 56 (comp) | PR21 | 67.9 | 21.5 | 3.01 | 34.6 | 24.8 |
| 57 | PR22 | 19.5 | 16.5 | 3.89 | 26.6 | 17.2 |
| 58 (comp) | PR23 | 21.3 | 17.0 | 3.96 | 29.3 | 18.2 |

TABLE 9b

| | Photo- | 37 nm/74 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 59 | PR20 | 83.2 | 18.7 | 4.47 | 33.9 | 40.8 |
| 60 (comp) | PR21 | 94.9 | 14.9 | 6.67 | 37.6 | 65.0 |
| 61 | PR22 | 28.5 | 16.6 | 5.69 | 21.7 | 30.3 |
| 62 (comp) | PR23 | 31.3 | 16.6 | 5.93 | 24.4 | 33.2 |

TABLE 9c

| | | |
|---|---|---|
| Photoresist | 34 nm/74 p | 32 nm/74 p |

| | | | | | |
|---|---|---|---|---|---|
| Example | Composition | E_{size} | LWR | E_{size} | LWR |

| | | | |
|---|---|---|---|
| 63 | PR20 | 35.9 nm | 34.9 nm |
| | | (collapsed) | (collapsed) |
| 64 (comp) | PR21 | 39.0 nm | 37.4 nm |
| | | (collapsed) | (collapsed) |

| | | | | | |
|---|---|---|---|---|---|
| 65 | PR22 | 26.9 | 4.66 | 25.3 | 4.71 |
| 66 (comp) | PR23 | 29.6 | 4.88 | 27.8 | 5.04 |

### CHOMMA/α-GBLMA/NLMA Copolymer Synthesis

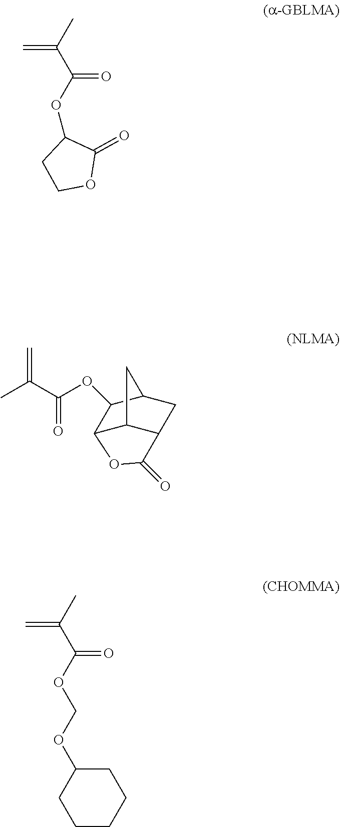 [SMILES: C=C(C)C(=O)OC1CCOC1=O ; C=C(C)C(=O)OC1C2CC3C(=O)OC1C3C2 ; C=C(C)C(=O)OCOC1CCCCC1]

### Triblock Copolymer Synthesis. (CHOMMA/α-GBLMA/NLMA)

The triblock Copolymer 14 was prepared as follows. A monomer solution of 9.5 g of α-GBLMA, 11.1 g of CHOMMA, and 6.2 g of NLMA was prepared in 17.9 g of 1,4-dioxane. 10.0 g of the monomer solution was mixed with 82 mg of V601 initiator as the feed solution. The feed solution was degassed and taken into a syringe before use. In the reactor, 247 mg of 2-cyano-2-propyl dodecyl trithiocarbonate was used as the CTA and protected under N₂ at 85° C. One third of the feed solution was added to the CTA and heated for 120 minutes; another one third of the feed solution was added to the reactor and heated to 85° C. for another 120 minutes; and the remainder of the feed solution was added to the reactor at 85° C. and reacted for 150 minutes. Aliquots were taken from the reaction mixture under gentle N₂ flow when needed. The conversions were found to be >97%. The reaction mixture was diluted with PGMEA and precipitated into isopropanol.

### Tetrablock Copolymer Synthesis. (CHOMMA/α-GBLMA/NLMA)

The multiblock Copolymer 15 was prepared using an analogous procedure as was used to prepare Copolymer 14.

### Comparative Copolymer. (CHOMMA/α-GBLMA/NLMA)

The random Copolymer 16 (comparative) was prepared following a similar procedure as for Copolymer 8, using a monomer molar ratio of 40/40/20.

The block copolymers and comparative copolymers derived from the monomer combination CHOMMA/α-GBLMA/NLMA (40/40/20 mole ratio) are summarized in Table 10.

TABLE 10

| | | End-group | Mₙ | M_{w} | |
|---|---|---|---|---|---|
| Copolymer | Structure | removal | (g/mol) | (g/mol) | Ð |
| 14 | Triblock | No | 5900 | 7500 | 1.27 |
| 15 | Tetrablock | No | 5800 | 7500 | 1.29 |
| 16 (comp) | Random | | 4300 | 8600 | 2.02 |

M_{w}. Mₙ, and dispersity index (D) were determined by GPC using polystyrene standards.

### Photoresist Preparation

Positive tone photoresist compositions PR24 to PR29 were prepared by dissolving solid components (copolymer, PAG, quencher, and additive) in solvents using the materials and amounts indicated in Table 11, where the amounts are expressed in wt % based on 100 wt % of total weight of the solids. The total solids content for the photoresist compositions was 2.9%. The solvent system contained PGMEA (S1) and 2-hydroxyisobutyric acid methyl ester (S2). Each mixture was shaken in a 100 mL glass container on a mechanical shaker and filtered through a PTFE disk-shaped filter having a pore size of 0.20 micrometers.

TABLE 11

| Photoresist | | | | | |
|---|---|---|---|---|---|
| Composition | Copolymer | PAG | Quencher | Additive | Solvent |
| PR24 | 14 | TBPTO C1 | DPIC | E1 | S1 / S2 |
| | [83.41] | [10.49] | [3.1] | [3] | [35:65 w/w] |
| PR25 | 15 | TBPTO C1 | DPIC | E1 | S1 / S2 |
| | [83.41] | [10.49] | [3.1] | [3] | [35:65 w/w] |
| PR26 (comp) | 16 (comp) | TBPTO C1 | DPIC | E1 | S1 / S2 |
| | [83.41] | [10.49] | [3.1] | [3] | [35:65 w/w] |
| PR27 | 14 | TDPS IAD | DPIC | E1 | S1 / S2 |
| | [79.60] | [15.05] | [2.32] | [3] | [35:65 w/w] |
| PR28 | 15 | TDPS IAD | DPIC | E1 | S1 / S2 |
| | [79.60] | [15.05] | [2.32] | [3] | [35:65 w/w] |
| PR29 (comp) | 16 (comp) | TDPS IAD | DPIC | E1 | S1 / S2 |
| | [79.60] | [15.05] | [2.32] | [3] | [35:65 w/w] |

### Lithographic Testing—Examples 67 to 91

### E_{size}, EL %, LWR, and PCM Evaluation

300 mm silicon wafers were spin-coated with AR™ 40A antireflectant (DuPont Electronics & Industrial) using a cure temperature of 205° C. for 60 seconds to form a first BARC layer having a thickness of 80 nm. The wafers were then spin-coated with AR™ 104 antireflectant (DuPont Electronics & Industrial) using a cure temperature of 175° C. for 60 seconds to form a second BARC layer having a thickness of 40 nm. The wafers were then spin-coated with a respective photoresist composition from Table 11 and soft-baked at 90° C. for 60 seconds to provide a photoresist layer having a thickness of 90 nm. The BARC and photoresist layers were coated with a TEL CLEAN TRACK™ LITHIUS™ coating tool. The wafers were exposed to 193 nm activating radiation using ASML 1900i immersion scanner (1.35 NA, 0.988/0.90 inner/outer sigma, dipole illumination with 35Y polarization) using a mask having line-space patterns (38 nm linewidth/76 nm pitch, 37 nm linewidth/74 nm pitch, 34 nm linewidth/74 nm pitch, or 32 nm linewidth/74 nm pitch) at various doses. The exposed wafers were post-exposure baked at 95° C. for 60 seconds and developed with a 0.26 N aqueous TMAH solution (MF™-CD26, DuPont Electronics & Industrial) for 12 seconds. The wafers were then rinsed with DI water and spin-dried to form photoresist patterns. CD linewidth measurements of the formed patterns were made using a Hitachi High Technologies Co. CG4000 CD-SEM.

Line-space patterns in nanometers (nm) were analyzed for critical dimension (CD), where sizing energy “E_{size}” is the irradiation energy when the CD of the formed line-space pattern is equal to the CD of the mask pattern. E_{size} is expressed in units of millijoules per square centimeter (mJ/cm²). Exposure latitude (EL %) is the difference in exposure energy required to print the line-space patterns at plus and minus 10% of the target diameter, normalized by the sizing energy. Linewidth roughness (LWR) is expressed in units of nanometers (nm) and was determined as the 3-sigma value from the distribution of a total of 100 arbitrary points of line width measurements, followed by removing metrology noise. PCM is pattern collapse margin, which is expressed in units of nanometers. The E_{size}, EL %, LWR, and PCM data are shown in Tables 12a, 12b, and 12c.

TABLE 12a

| | Photo- | 38 nm/76 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 68 | PR24 | 30.9 | 25.13 | 2.19 | 32.5 | 12.2 |
| 69 | PR25 | 30.2 | 23.67 | 2.17 | 33.9 | 12.0 |
| 70 (comp) | PR26 (comp) | 25.2 | 33.09 | 2.31 | 32.9 | 11.6 |
| 71 | PR27 | 11.7 | 25.92 | 2.86 | 27.1 | 9.8 |
| 72 | PR28 | 12.1 | 21.00 | 2.90 | 28.5 | 10.1 |
| 73 (comp) | PR29 (comp) | 12.0 | 18.84 | 2.72 | 28.2 | 9.3 |

TABLE 12b

| | Photo- | 37 nm/74 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 74 | PR24 | 43.1 | 23.88 | 3.47 | 33.3 | 22.8 |
| 75 | PR25 | 43.4 | 23.76 | 3.48 | 34.2 | 22.9 |
| 76 (comp) | PR26 (comp) | 35.5 | 23.70 | 3.44 | 34.8 | 20.5 |
| 77 | PR27 | 17.1 | 16.10 | 4.59 | 30.1 | 19.1 |
| 78 | PR28 | 17.1 | 18.65 | 4.62 | 24.9 | 19.1 |
| 79 (comp) | PR29 (comp) | 16.8 | 18.94 | 4.80 | 30.4 | 19.7 |

TABLE 12c

| | Photo- | 34 nm/74 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 80 | PR24 | 37.6 | 10.6 | 3.09 | 32.9 | 19.1 |
| 81 | PR25 | 36.6 | 9.9 | 3.04 | 32.6 | 18.2 |
| 82 (comp) | PR26 (comp) | 31.3 | 10.1 | 3.18 | 30.8 | 17.9 |
| 83 | PR27 | 15.9 | 14.7 | 3.91 | 29.3 | 15.5 |
| 84 | PR28 | 16.1 | 15.2 | 3.88 | 28.2 | 15.5 |
| 85 (comp) | PR29 (comp) | 15.5 | 15.2 | 4.16 | 32.4 | 16.3 |

TABLE 12d

| | Photo- | 32 nm/74 p | | | | |
|---|---|---|---|---|---|---|
| | resist | | | | | LWR |
| | Com- | | | | | * sqrt |
| Example | position | E_{size} | EL % | LWR | PCM | (E_{size}) |
| 86 | PR24 | 34.9 | 9.5 | 3.36 | 31.2 | 20.1 |
| 87 | PR25 | 34.2 | 11.9 | 3.37 | 28.5 | 19.9 |
| 88 (comp) | PR26 (comp) | 28.8 | 12.2 | 3.48 | 30.3 | 18.5 |
| 89 | PR27 | 14.9 | 13.4 | 4.57 | 28.3 | 17.3 |
| 90 | PR28 | 14.9 | 13.1 | 4.21 | 29.1 | 18.1 |
| 91 (comp) | PR29 (comp) | 14.6 | 14.0 | 4.90 | 31.2 | 18.5 |

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A block copolymer, comprising:
a first block comprising two or more structurally different repeating units;
a second block comprising two or more structurally different repeating units;
a repeating unit of the first block comprises an acid-labile group, a lactone group, a salt group, or a hydroxyaryl group; and
a repeating unit of the second block comprises an acid-labile group, a lactone group, a salt group, or a hydroxyaryl group,
wherein the two or more structurally different repeating units of the first block are the same as the two or more structurally different repeating units of the second block.

2. The block copolymer of claim 1, wherein the two or more structurally different repeating units of the first block and the two or more structurally different repeating units of the second block are present in the first block and the second block in substantially the same ratios, and each block has the same structural unit gradient direction from a first end to a second end of the block.

3. The block copolymer of claim 1, wherein the first block and the second block each comprises a repeating unit comprising an acid-labile group.

4. The block copolymer of claim 1, wherein the first block and the second block each comprises a repeating unit comprising a lactone group or a salt group.

5. The block copolymer of claim 1, wherein an average number of repeating units within each block is 5 or more.

6. The block copolymer of claim 1, wherein an average number of blocks in the block copolymer is from 3 to 10.

7. The block copolymer of claim 1, further comprising a block that does not have the same structurally different repeating units as the first block and the second block.

8. A polymer, comprising one or more block copolymers of claim 1 bonded to another part of the polymer.

9. A photoresist composition, comprising a block copolymer of claim 1, and a solvent.

10. A pattern forming method, comprising:
forming on a substrate a photoresist composition layer from the photoresist composition of claim 9;
pattern-wise exposing the photoresist composition layer to activating radiation; and
developing the exposed photoresist composition layer to provide a resist relief image.

11. The photoresist composition of claim 9, wherein the two or more structurally different repeating units of the first block and the two or more structurally different repeating units of the second block are present in the first block and the second block in substantially the same ratios, and each block has the same structural unit gradient direction from a first end to a second end of the block.

12. The photoresist composition of claim 9, wherein the first block and the second block each comprises a repeating unit comprising an acid-labile group.

13. The photoresist composition of claim 9, wherein the first block and the second block each comprises a repeating unit comprising a lactone group or a salt group.

14. The photoresist composition of claim 9, wherein an average number of repeating units within each block is 5 or more.

15. The photoresist composition of claim 9, wherein an average number of blocks in the block copolymer is from 3 to 10.

16. The photoresist composition of claim 9, further comprising a block that does not have the same structurally different repeating units as the first block and the second block.

17. The pattern forming method of claim 10, wherein the two or more structurally different repeating units of the first block and the two or more structurally different repeating units of the second block are present in the first block and the second block in substantially the same ratios, and each block has the same structural unit gradient direction from a first end to a second end of the block.

18. The pattern forming method of claim 10, wherein the first block and the second block each comprises a repeating unit comprising an acid-labile group.

19. The pattern forming method of claim 10, wherein the first block and the second block each comprises a repeating unit comprising a lactone group or a salt group.

20. The pattern forming method of claim 10, further comprising a block that does not have the same structurally different repeating units as the first block and the second block
